(19) United States
(12) Patent Application Publication
(10) Pub. No.: US 2025/0056866 A1
(43) Pub. Date: Feb. 13, 2025

(54) SEMICONDUCTOR DEVICE

(71) Applicant: Taiwan Semiconductor Manufacturing Co., Ltd., Hsinchu (TW)

(72) Inventor: Jhon-Jhy LIAW, Zhudong Township (TW)

(73) Assignee: Taiwan Semiconductor Manufacturing Co., Ltd., Hsinchu (TW)

(21) Appl. No.: 18/447,802

(22) Filed: Aug. 10, 2023

(51) Int. Cl. H01L 29/417; H01L 27/092; H01L 29/06; H01L 29/423; H01L 29/45; H01L 29/775

(52) U.S. Cl. CPC H01L 29/41775; H01L 27/092; H01L 29/0673; H01L 29/42392; H01L 29/456; H01L 29/775

(57) ABSTRACT

A semiconductor device includes circuit cells having transistors. Each of the transistors includes nanostructures vertically stacked from each other in a Z-direction, a gate structure wrapping around the nanostructures and extending in a Y-direction, and source/drain features on opposite sides of the gate structure in an X-direction. The semiconductor device further includes silicide features over and in contact with the source/drain features. The silicide features extend lower than bottom surfaces of topmost nanostructures of the nanostructures. The semiconductor device further includes source/drain contacts over and in contact with the silicide features. Each of bottom surfaces of the source/drain contacts has a V-shape in an X-Z cross-sectional view.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) transistors have been incorporated into memory devices (including, for example, static random-access memory, or SRAM, cells) and core devices (including, for example, standard logic, or STD, cells) to reduce chip footprint while maintaining reasonable processing margins.

However, as GAA transistors and circuit cells continue to be scaled down, existing contact features for source/drain features impact the isolation margin as well as cost. Accordingly, although existing technologies for fabricating circuit cells including GAA transistors have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a fragmentary diagrammatic top view of an integrated circuit (IC) chip, in portion or entirety, in accordance with some embodiments of the present disclosure.

FIGS. 2A, 2B, 2C, 2D, and 2E are circuit schematics of various STD cells in the array of circuit cells in the logic region of the IC chip, in accordance with some embodiments of the present disclosure.

FIG. 3 is a perspective view of an embodiment of a GAA transistor in the array of circuit cells, in accordance with some embodiments of the present disclosure.

FIGS. 4A and 4B illustrate top views (or layouts) of an array of circuit cells in the logic region of the IC chip, in accordance with some embodiments of the present disclosure.

FIG. 4C illustrates an X-Z cross-sectional view of the array of the circuit cells along a line C-C′ in FIGS. 4A and 4B, in accordance with some embodiments of the present disclosure.

FIG. 4D illustrates an X-Z cross-sectional view of the array of the circuit cells along a line D-D′ in FIGS. 4A and 4B, in accordance with some embodiments of the present disclosure.

FIG. 4E illustrates a Y-Z cross-sectional view of the array of the circuit cells along a line E-E′ in FIGS. 4A and 4B, in accordance with some embodiments of the present disclosure.

FIG. 4F illustrates a Y-Z cross-sectional view of the array of the circuit cells along a line F-F′ in FIGS. 4A and 4B, in accordance with some embodiments of the present disclosure.

FIG. 5A illustrates an X-Z cross-sectional view of the array of the circuit cells along a line D-D′ in FIGS. 4A and 4B, in accordance with some alternative embodiments of the present disclosure.

FIG. 5B illustrates a Y-Z cross-sectional view of the array of the circuit cells along a line F-F′ in FIGS. 4A and 4B, in accordance with some alternative embodiments of the present disclosure.

FIG. 6 illustrates a Y-Z cross-sectional view of the array of the circuit cells along a line F-F′ in FIGS. 4A and 4B, in accordance with some alternative embodiments of the present disclosure.

FIG. 7 illustrates an X-Z cross-sectional view of the array of the circuit cells along a line C-C′ in FIGS. 4A and 4B, in accordance with some alternative embodiments of the present disclosure.

FIGS. 8A, 8B, 8C, 8D, 8E, 8F, 8G, 8H, and 8I are cross-sectional views of a device at various fabrication stages, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures of circuit cells having field-effect transistors (FETs), such as three-dimensional gate-all-around (GAA) transistors, in an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it should be understood that other embodiments may offer different advantages, not all advantages are necessarily discussed herein, and no particular advantage is required for all embodiments. For example, embodiments discussed herein include circuit cells having transistors with V-shaped silicide features, such that source/drain contacts are enlarged to reduce the resistance. The details of the present disclosure are described below in conjunction with the accompanying drawings, which illustrate the layout and structure of circuit cells, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise noted.

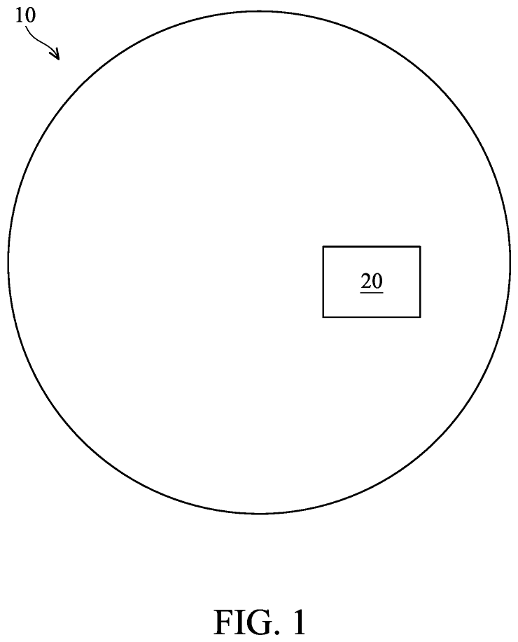

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, P-type field effect transistors (PFETs), N-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or combinations thereof. The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. As shown in FIG. 1, the IC chip 10 includes a logic region 20. The logic region 20 may include an array of circuit cells having various logic cells or standard (STD) cells. The logic cells or STD cells may include transistors and interconnect structures that combine to provide a logic device and/or a logic function, such as an inverter, an AND, an NAND, an OR, an NOR, a NOT, an XOR, an XNOR, a Flip-Flop, other suitable logic devices, or combinations thereof. FIG. 1 has been simplified for the sake of clarity to better understand the inventive concepts of the present disclosure. Additional features can be added in the IC chip 10, and some of the features described herein can be replaced, modified, or eliminated in other embodiments of the IC chip 10.

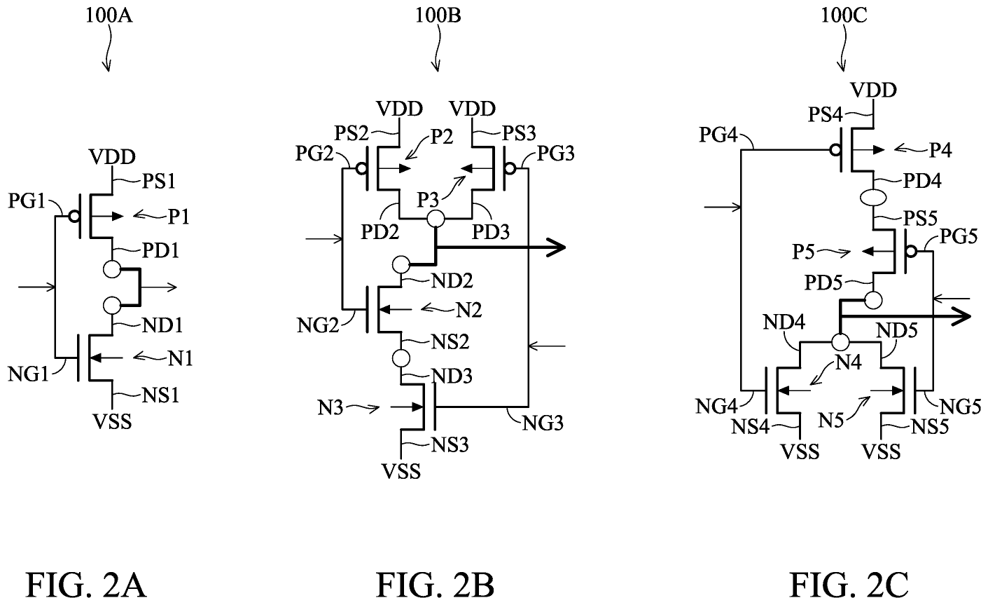

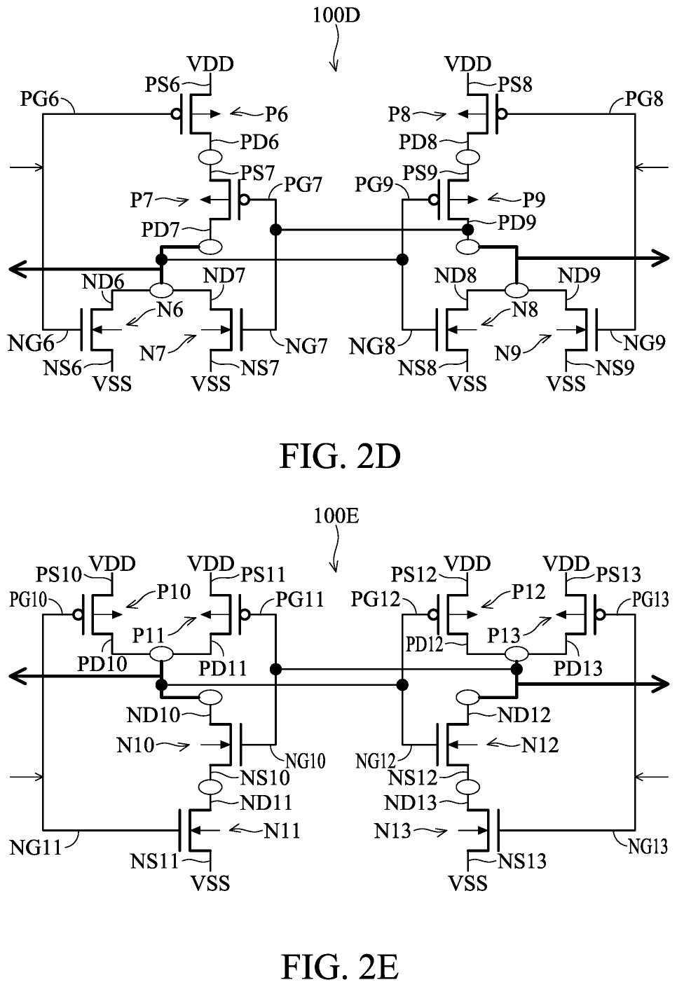

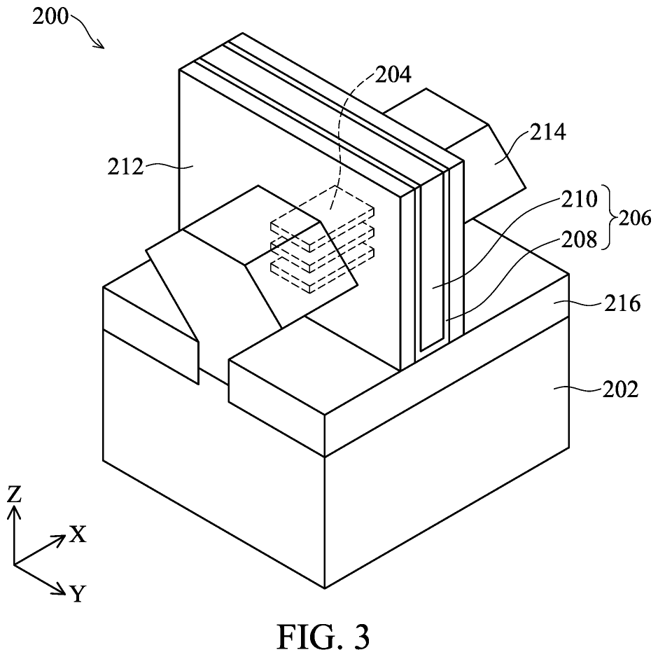

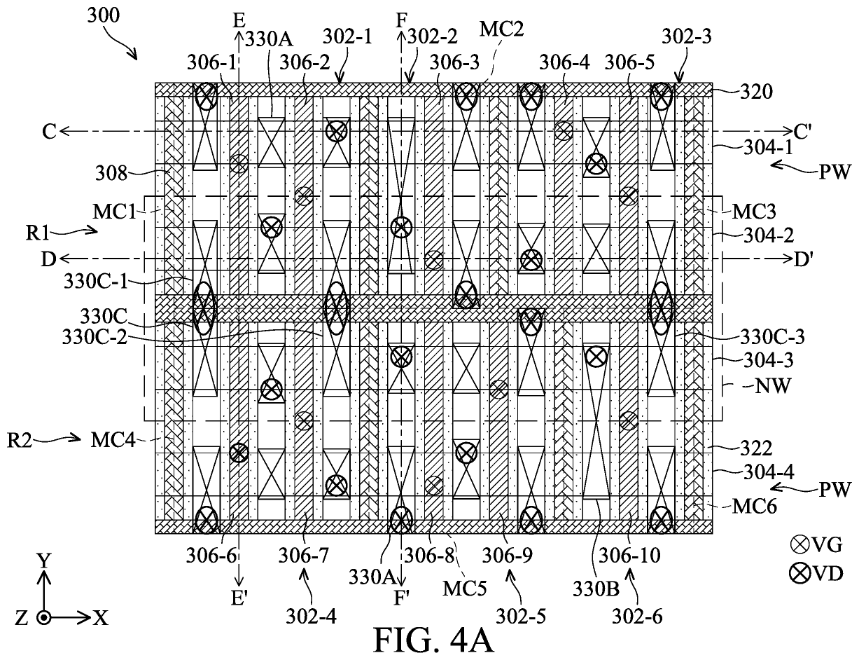

FIGS. 2A to 2E are circuit schematics of various STD cells in the array of circuit cells in the logic region 20 of the IC chip 10, in accordance with some embodiments of the present disclosure.

FIG. 2A shows an inverter 100A including an N-type transistor N1 and a P-type transistor P1. The N-type transistor N1 includes a source terminal NS1, a drain terminal ND1, and a gate terminal NG1, and the P-type transistor P1 includes a source terminal PS1, a drain terminal PD1, and a gate terminal PG1.

As shown in FIG. 2A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B shows a NAND (also referred to as a NAND logic gate, a NAND device or a NAND cell) 100B including N-type transistors N2, N3 and P-type transistors P2, P3. The N-type transistor N2 includes a source terminal NS2, a drain terminal ND2, and a gate terminal NG2, and the N-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B, and the gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as a “common drain.” The source terminals PS2 and PS3 are coupled to the VDD voltage. The source terminal NS3 is coupled to VSS voltage (or a ground voltage). The source terminal NS2 and drain terminal ND3 are coupled with each other.

FIG. 2C shows a NOR (also referred to as a NOR logic gate, a NOR device or a NOR cell) 100C including N-type transistors N4, N5 and P-type transistors P4, P5. The N-type transistor N4 includes a source terminal NS4, a drain terminal ND4, and a gate terminal NG4, and the N-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage (or a ground voltage). The source terminal PS5 and drain terminal PD4 are coupled with each other.

FIG. 2D shows a flip-flop (also referred to as a flip-flop device or a flip-flop cell) 100D including N-type transistors N6, N7, N8, N9 and P-type transistors P6, P7, P8, P9. The N-type transistor N6 includes a source terminal NS6, a drain terminal ND6, and a gate terminal NG6; the N-type transistor N7 includes a source terminal NS7, a drain terminal ND7, and a gate terminal NG7; the N-type transistor N8 includes a source terminal NS8, a drain terminal ND8, and a gate terminal NG8; and the N-type transistor N9 includes a source terminal NS9, a drain terminal ND9, and a gate terminal NG9. The P-type transistor P6 includes a source terminal PS6, a drain terminal PD6, and a gate terminal PG6; the P-type transistor P7 includes a source terminal PS7, a drain terminal PD7, and a gate terminal PG7; the P-type transistor P8 includes a source terminal PS8, a drain terminal PD8, and a gate terminal PG8; and the P-type transistor P9 includes a source terminal PS9, a drain terminal PD9, and a gate terminal PG9.

As shown in FIG. 2D, the flip-flop 100D is a set-reset (SR) NOR latch. The NOR latch may include a pair of cross-coupled NOR. Specifically, the output terminal of a first NOR is coupled to the second input terminal of a second NOR, and the output terminal of the second NOR is coupled to the second input terminal of the first NOR. The details of the other connections of the flip-flop 100D are similar to the NOR 100C, and may not be described in detail herein.

FIG. 2E shows a flip-flop 100E including N-type transistors N10, N11, N12, N13 and P-type transistors P10, P11, P12, P13. The N-type transistor N10 includes a source terminal NS10, a drain terminal ND10, and a gate terminal NG10; the N-type transistor N11 includes a source terminal NS11, a drain terminal ND11, and a gate terminal NG11; the N-type transistor N12 includes a source terminal NS12, a drain terminal ND12, and a gate terminal NG12; and the N-type transistor N13 includes a source terminal NS13, a drain terminal ND13, and a gate terminal NG13. The P-type transistor P10 includes a source terminal PS10, a drain terminal PD10, and a gate terminal PG10; the P-type transistor P11 includes a source terminal PS11, a drain terminal PD11, and a gate terminal PG11; the P-type transistor P12 includes a source terminal PS12, a drain terminal PD12, and a gate terminal PG12; and the P-type transistor P13 includes a source terminal PS13, a drain terminal PD13, and a gate terminal PG13.

As shown in FIG. 2E, the flip-flop 100E is a SR NAND latch. The NAND latch may include a pair of cross-coupled NAND. Specifically, the output terminal of a first NAND is coupled to the first input terminal of a second NAND, and the output terminal of the second NAND is coupled to the first input terminal of the first NAND. The details of the other connections of the flip-flop 100E are similar to the NAND 100B, and may not be described in detail herein.

Each of the circuit cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, an exemplary GAA transistor is illustrated in FIG. 3. However, it should be understood that the application should not be limited to a particular type of device, except as specifically claimed.

Referring to FIG. 3, a perspective view of an exemplary GAA transistor 200 is illustrated. The GAA transistor 200 is formed over a substrate 202. The substrate 202 may contains a semiconductor material, such as bulk silicon (Si). The GAA transistor 200 also includes one or more nanostructures 204 (dash lines) extending in the X-direction and vertically stacked (or arranged) in the Z-direction. More specifically, the nanostructures 204 are spaced from each other in the Z-direction. In some embodiments, the nanostructures 204 may also be referred to as channels, channel layers, nanosheets, or nanowires.

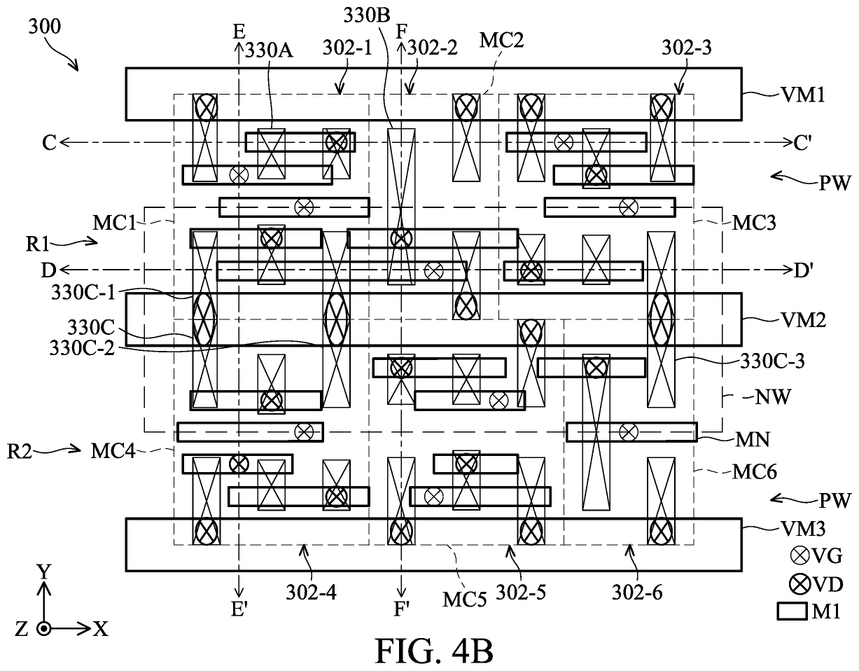

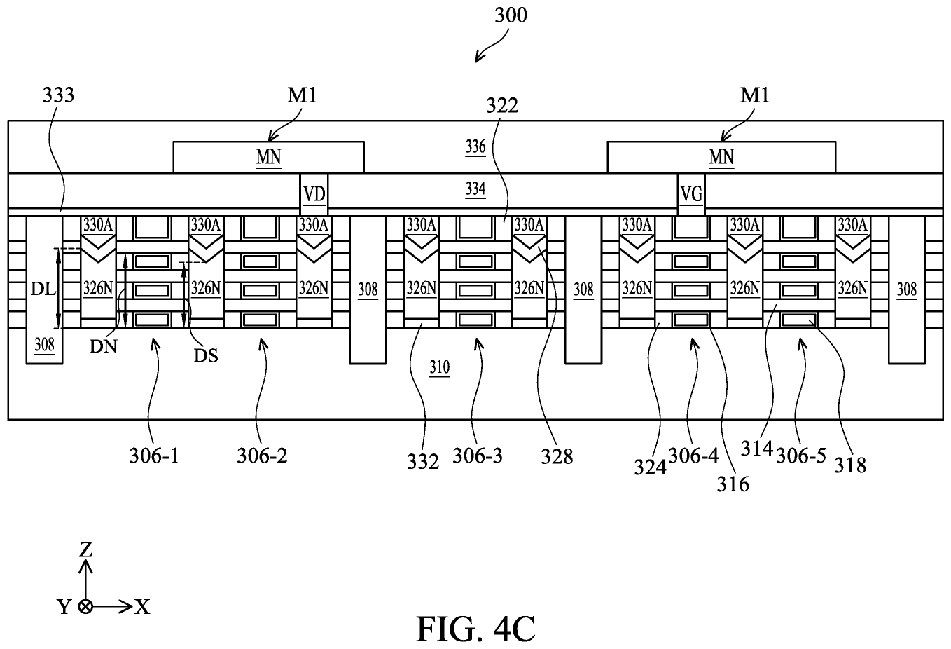

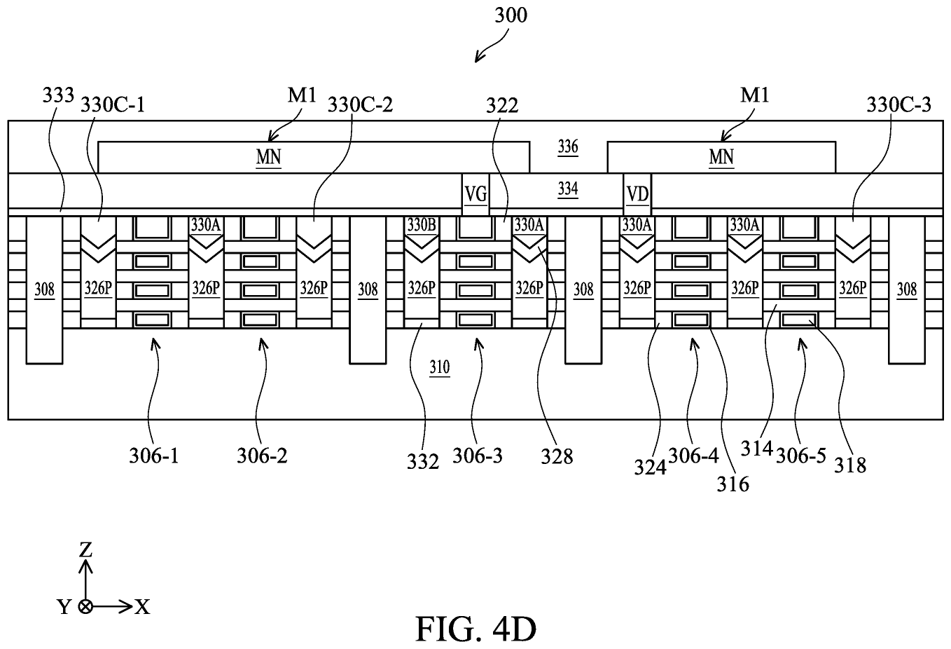

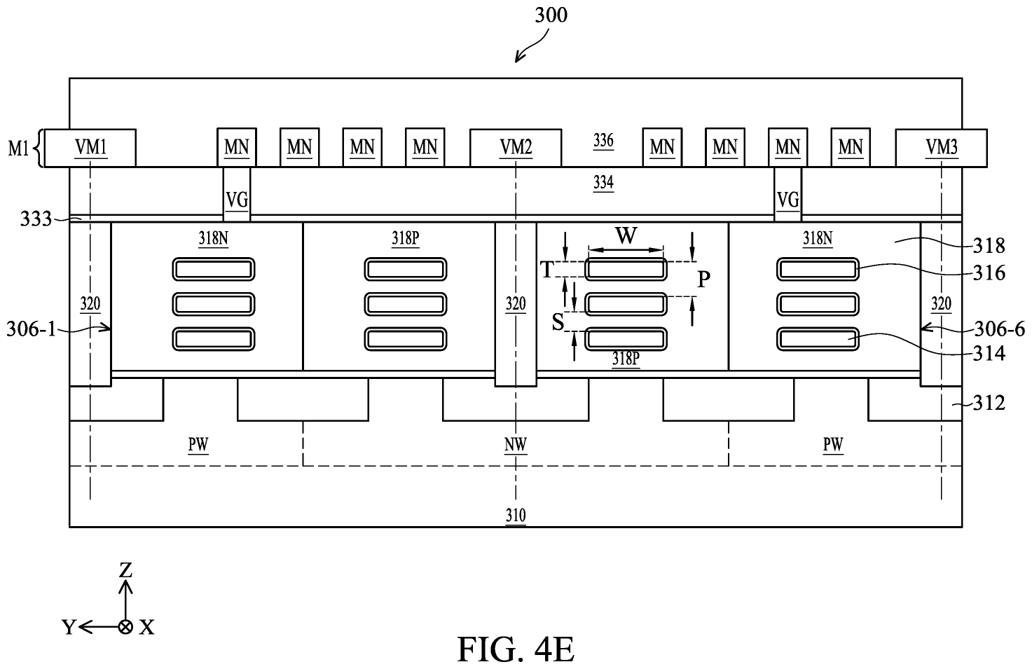

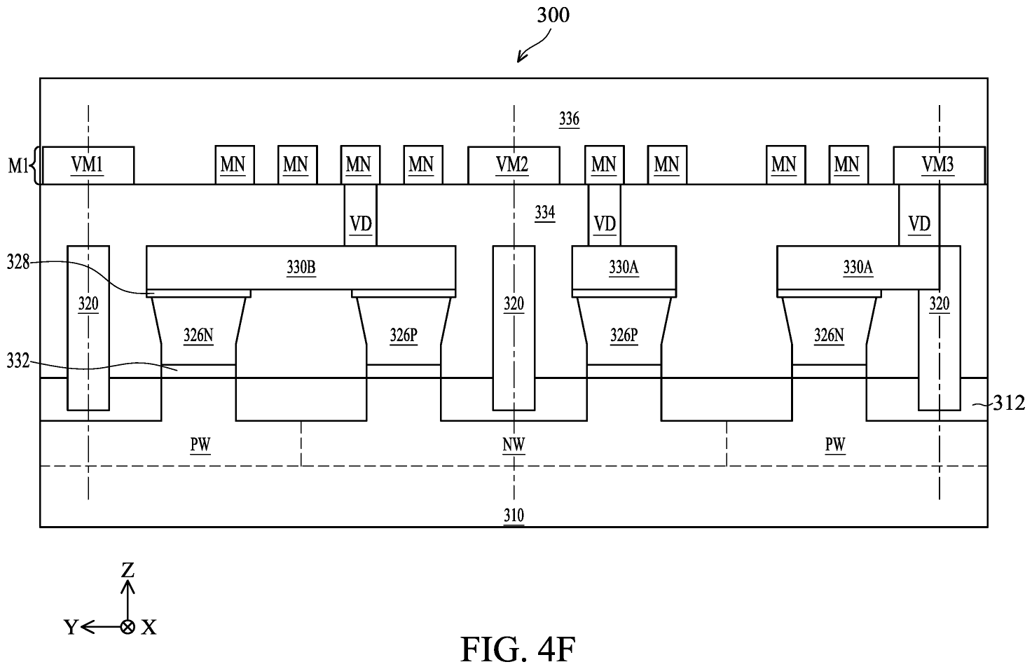

The GAA transistor 200 further includes a gate structure 206 including a gate dielectric layer 208 and a gate electrode 210. The gate dielectric layer 208 wraps around the nanostructures 204 and the gate electrode 210 wraps around the gate dielectric layer 208 (not shown in FIG. 2, may refer to FIGS. 4C, 4D, and 4E). As shown in FIG. 2, gate spacers 212 are on sidewalls of the gate structure 206 and over the nanostructures 204 (not shown in FIG. 2, may refer to FIGS. 4C and 4D)

The GAA transistor 200 further includes source/drain features 214. As shown in FIG. 2, two source/drain features 214 are on opposite sides of the gate structure 206. The nanostructures 204 (dash lines) extend in the X-direction to connect one source/drain feature 214 to the other source/drain feature 214. The source/drain features 214 may also be referred to as source/drain, or source/drain regions. In some embodiments, source/drain feature(s) may refer to a source or a drain, individually or collectively dependent upon the context.

Isolation feature 216 is over the substrate 202 and under the gate dielectric layer 208, the gate electrode 210, and the gate spacers 212. The isolation feature 216 is used for isolating the GAA transistor 200 from other devices. In some embodiments, the isolation feature 216 may include different structures, such as shallow trench isolation (STI) structure, deep trench isolation (DTI) structure. Therefore, the isolation feature 216 is also referred as to as a STI feature or DTI feature.

FIGS. 4A and 4B illustrate top views (or layouts) of an array 300 of circuit cells in the logic region 20 of the IC chip 10, in accordance with some embodiments of the present disclosure. FIG. 4A illustrates features of transistors and vias connected to contact features and/or gate structures of the transistors, and FIG. 4B illustrates the contact features of the transistors, the vias, and metal lines.

FIG. 4C illustrates an X-Z cross-sectional view of the array 300 of the circuit cells along a line C-C′ in FIGS. 4A and 4B, in accordance with some embodiments of the present disclosure. FIG. 4D illustrates an X-Z cross-sectional view of the array 300 of the circuit cells along a line D-D′ in FIGS. 4A and 4B, in accordance with some embodiments of the present disclosure. FIG. 4E illustrates a Y-Z cross-sectional view of the array 300 of the circuit cells along a line E-E′ in FIGS. 4A and 4B, in accordance with some embodiments of the present disclosure. FIG. 4F illustrates a Y-Z cross-sectional view of the array 300 of the circuit cells along a line F-F′ in FIGS. 4A and 4B, in accordance with some embodiments of the present disclosure.

The array 300 may include circuit cells, for example standard circuit cells (also referred to STD cells). As discussed above, the STD cells may include logic circuits or logic devices, including but not limited to logic circuits such as inverters, NANDs, NORs, flip-flops, or a combination thereof. For the sake of providing an example, the array 300 shows a row R1 having circuit cell 302-1 (which includes a NAND) with a cell boundary MC1, circuit cell 302-2 (which includes an inverter) with a cell boundary MC2, and circuit cell 302-3 (which includes an NOR) with a cell boundary MC3; and a row R2 having circuit cell 302-4 (which includes a NAND) with a cell boundary MC4, circuit cell 302-5 (which includes an NOR) with a cell boundary MC5, and circuit cell 302-6 (which includes an inverter) with a cell boundary MC6. It should be understood that the circuit cells 302-1 to 302-6 are merely examples. The present disclosure applies to other types of STD cells as well, for example cells including NORs, ANDs, ORs, flip-flops, or a combination thereof.

The array 300 includes active areas, such as active areas 304-1 to 304-4, (may be collectively referred to as the active areas 304) that extend lengthwise in the X-direction. Each of active areas 304 includes channel regions, source regions, and drain regions (where source regions and drain regions are collectively referred to as source/drain regions herein) of transistors (e.g., the GAA transistor 200) of the array 300. The active areas 304-2 and 304-3 are disposed over an N-type well (or N-Well) NW. The active areas 304-1 and 304-4 are disposed over P-type wells (or P-Wells) PW that are on both sides of the N-type well NW in the Y-direction.

The array 300 further includes gate structures, such as gate structures 306-1 to 306-10 (may be collectively referred to as the gate structures 306). The gate structures 306-1 to 306-10 extend substantially parallel to one another, extend lengthwise in the Y-direction perpendicular to the X-direction, and are separated from each other in the X-direction, as shown in FIG. 4A. The gate structures 306-1 to 306-10 are disposed over the channel regions of the respective active areas 304-1 to 304-4 (i.e., the (vertically stacked) nanostructures) and disposed between respective source/drain regions of the active areas 304-1 to 304-4 (i.e., P-type source/drain features and/or N-type source/drain features, respectively). In some embodiments, gate structures 306-1 to 306-10 wrap and/or surround suspended, vertically stacked nanostructures 314 in the channel regions of the active areas 304-1 to 304-4, respectively (as shown in FIG. 4E). More specifically, as shown in FIGS. 4A to 4E, each of the gate structures 306-1 to 306-10 wrap around the nanostructures 314 in the channel regions of two of the active areas 304-1 to 304-4. For example, the gate structure 306-1 wraps around the nanostructures 314 in the active area 304-1 over the P-type well PW and the nanostructures 314 in the active area 304-2 over the N-type well NW.

The active areas 304-1 to 304-4 and the gate structures 306-1 to 306-10 are configured to provide each of circuit cells 302-1 to 302-6 with transistors. In the circuit cell 302-1, the gate structure 306-1 engages the active area 304-1 to construct an N-type transistor similar to the N-type transistor N3 of the NAND 100B discussed above, the gate structure 306-1 engages the active area 304-2 to construct a P-type transistor similar to the P-type transistor P3 of the NAND 100B discussed above, the gate structure 306-2 engages the active area 304-1 to construct an N-type transistor similar to the N-type transistor N2 of the NAND 100B discussed above, and the gate structure 306-2 engages the active area 304-2 to construct a P-type transistor similar to the P-type transistor P2 of the NAND 100B discussed above.

In the circuit cell 302-2, the gate structure 306-3 engages the active area 304-1 to construct an N-type transistor similar to the N-type transistor N1 of the inverter 100A discussed above, and the gate structure 306-3 engages the active area 304-2 to construct a P-type transistor similar to the P-type transistor P1 of the inverter 100A discussed above.

In the circuit cell 302-3, the gate structure 306-4 engages the active area 304-1 to construct an N-type transistor similar to the N-type transistor N5 of the NOR 100C discussed above, the gate structure 306-4 engages the active area 304-2 to construct a P-type transistor similar to the P-type transistor P5 of the NOR 100C discussed above, the gate structure 306-5 engages the active area 304-1 to construct an N-type transistor similar to the N-type transistor N4 of the NOR 100C discussed above, and the gate structure 306-5 engages the active area 304-2 to construct a P-type transistor similar to the P-type transistor P4 of the NOR 100C discussed above.

In the circuit cell 302-4, the gate structure 306-6 engages the active area 304-3 to construct a P-type transistor similar to the P-type transistor P3 of the NAND 100B discussed above, the gate structure 306-6 engages the active area 304-4 to construct an N-type transistor similar to the N-type transistor N3 of the NAND 100B discussed above, the gate structure 306-7 engages the active area 304-3 to construct a P-type transistor similar to the P-type transistor P2 of the NAND 100B discussed above, and the gate structure 306-7 engages the active area 304-4 to construct an N-type transistor similar to the N-type transistor N2 of the NAND 100B discussed above.

In the circuit cell 302-5, the gate structure 306-8 engages the active area 304-3 to construct a P-type transistor similar to the P-type transistor P5 of the NOR 100C discussed above, the gate structure 306-8 engages the active area 304-4 to construct an N-type transistor similar to the N-type transistor N5 of the NOR 100C discussed above, the gate structure 306-9 engages the active area 304-3 to construct a P-type transistor similar to the P-type transistor P4 of the NOR 100C discussed above, and the gate structure 306-9 engages the active area 304-4 to construct an N-type transistor similar to the N-type transistor N4 of the NOR 100C discussed above.

In the circuit cell 302-6, the gate structure 306-10 engages the active area 304-3 to construct a P-type transistor similar to the P-type transistor P1 of the inverter 100A discussed above, and the gate structure 306-10 engages the active area 304-4 to construct an N-type transistor similar to the N-type transistor N1 of the inverter 100A discussed above.

Therefore, the transistors used for circuit cells are formed. In some embodiments, the N-type transistors of the circuit cells 302-1 to 302-3 are arranged in the X-direction and share the active area 304-1, the P-type transistors of the circuit cells 302-1 to 302-3 are arranged in the X-direction and share the active area 304-2, the P-type transistors of the circuit cells 302-4 to 302-6 are arranged in the X-direction and share the active area 304-3, and the N-type transistors of the circuit cells 302-4 to 302-6 are arranged in the X-direction and share the active area 304-4. Further, each of the N-type transistors is arranged with one P-type transistor in the Y-direction and share one gate structure with that P-type transistor. For example, in the circuit cell 302-1, the N-type transistor similar to the N-type transistor N3 of the NAND 100B discussed above and the P-type transistor similar to the P-type transistor P3 of the NAND 100B discussed above are arranged in the Y-direction and share the gate structure 306-1.

The array 300 further includes dielectric gate structures 308 for separating the circuit cells 302-1 to 302-6 from each other in the X-direction. The dielectric gate structures 308 extend lengthwise in the Y-direction. The dielectric gate structures 308 and the circuit cells 302-1 to 302-6 (or the gate structures 306-1 to 306-10) are arranged in the X-direction. More specifically, in the row R1 of the array 300, four dielectric gate structures 308 and the circuit cells 302-1 to 302-3 (or the gate structures 306-1 to 306-5) are arranged in the X-direction, and four dielectric gate structures 308 separate or isolate the circuit cells 302-1 to 302-3 from each other. Similarly, in the row R2 of the array 300, four dielectric gate structures 308 and the circuit cells 302-4 to 302-6 (or the gate structures 306-6 to 306-10) are arranged in the X-direction, and four dielectric gate structures 308 separate or isolate the circuit cells 302-4 to 302-6 from each other.

Referring to FIGS. 4C to 4F, the array 300 includes a substrate 310, over which the various features are formed, such as the gate structures 306 and dielectric gate structures 308 above. The substrate 310 may contains a semiconductor material, such as bulk silicon (Si). In some other embodiments, the substrate 310 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). Alternatively, the substrate 310 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

The N-type well NW and P-type wells PW are formed in or on the substrate 310, as shown in FIGS. 4E and 4F. In the present embodiment, the P-type wells PW are P-type doped regions configured for N-type transistors, and the N-type well NW are N-type doped regions configured for P-type transistors. The N-type well NW is doped with N-type dopants, such as phosphorus, arsenic, other N-type dopant, or combinations thereof. The P-type wells PW are doped with P-type dopants, such as boron, indium, other P-type dopant, or combinations thereof. In some implementations, the substrate 310 includes doped regions formed with a combination of P-type dopants and N-type dopants. The various N-type wells and/or P-type wells can be formed directly on and/or in the substrate 310, for example, providing a p-well structure, an n-well structure, a dual-well structure, a raised structure, or combinations thereof. An ion implantation process, a diffusion process, and/or other suitable doping process can be performed to form the various wells.

Similar to the isolation feature 216 discussed above, the array 300 further includes an isolation feature (or isolation structure) 312 over the substrate 310 and isolating the adjacent active areas 304. The isolation feature 312 may include silicon oxide, silicon nitride, silicon oxynitride, other suitable isolation material (for example, including silicon, oxygen, nitrogen, carbon, or other suitable isolation constituent), or combinations thereof. The isolation feature 312 may include different structures, such as shallow trench isolation (STI) structures, deep trench isolation (DTI) structures, and/or local oxidation of silicon (LOCOS) structures. In some embodiments, STI features include a multi-layer structure that fills the trenches, such as a silicon nitride comprising layer disposed over a thermal oxide comprising liner layer. In another example, STI features include a dielectric layer disposed over a doped liner layer (including, for example, boron silicate glass (BSG) or phosphosilicate glass (PSG)). In yet another example, STI features include a bulk dielectric layer disposed over a liner dielectric layer, where the bulk dielectric layer and the liner dielectric layer include materials depending on design requirements.

Each of the transistors in the circuit cells 302-1 to 302-6 includes nanostructures 314 similar to the nanostructures 204 discussed above. As shown in FIGS. 4C to 4E, the nanostructures 314 are suspended over the N-type well NW and P-type wells PW of the substrate 310. In some embodiments, three nanostructures 314 are vertically stacked (or vertically arranged) from each other in the Z-direction for one transistor. However, there may be another appropriate number of nanostructures in one transistor. For example, there may be from 2 to 10 nanostructures 314 in one transistor. The nanostructures 314 further extend lengthwise in the X-direction (FIGS. 4C and 4D) and widthwise in the Y-direction (FIG. 4E). In some embodiments, each of the nanostructures 314 has a width W in the Y-direction and in a range from about 4 nm to about 100 nm, as shown in FIG. 4E. In some embodiments, each of the nanostructures 314 has a thickness T in the Z-direction and in a range from about 4 nm to about 10 nm, as shown in FIG. 4E. As shown in FIG. 4E, in each of the transistors in the circuit cells 302-1 to 302-6, three nanostructures 314 are spaced from each other in the Z-direction by a distance S in a range from about 4 nm to about 20 nm. In some embodiments, the nanostructures has vertically a pitch P in the Z-direction and in a range from about 8 nm to about 30 nm.

The nanostructures 314 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 314 include silicon for N-type transistors. In other embodiments, the nanostructures 314 include silicon germanium for P-type transistors. In some embodiments, the nanostructures 314 are all made of silicon, and the type of the transistors depend on work function metal layer wrapping around the nanostructures 314. In some embodiments, the nanostructures 314 are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

As discussed above, the gate structures 306-1 to 306-10 engage the active areas to construct the transistors. More specifically, the gate structures 306-1 to 306-10 wrap around the nanostructures 314 in the channel regions of the active areas 304-1 to 304-4. Each of the gate structures 306-1 to 306-10 has a gate dielectric layer 316 and a gate electrode layer 318. The gate dielectric layers 316 wrap around each of the nanostructures 314 and the gate electrode layers 318 wrap around the gate dielectric layer 316. In some embodiments, each of the gate structures 306 further includes an interfacial layer (such as having silicon dioxide, silicon oxynitride, or other suitable materials) between the gate dielectric layer 316 and the nanostructures 314. The gate dielectric layers 316 may include oxide with nitrogen doped dielectric material (initial layer) combined with metal content high-K dielectric material (K value (dielectric constant) >13). For example, gate dielectric layers 316 may include hafnium oxide (HfO₂), which has a dielectric constant in a range from about 18 to about 40. Alternatively, the gate dielectric layers 316 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layers 316 may be formed by chemical oxidation, thermal oxidation, ALD, CVD, and/or other suitable methods.

The gate electrode layer 318 is formed to wrap around the gate dielectric layer 316 and the center portions of the nanostructures 314, as shown in FIGS. 4C and 4D. In some embodiments, the gate electrode layer 318 may include an N-type work function metal layer 318N for N-type transistor or a P-type work function metal layer 318P for P-type transistor. The N-type work function metal layer 318N and the P-type work function metal layer 318P may be selected from a group consisting of TiN, TaN, TiAl, TiAlN, TaAl, TaAlN, TaAlC, TaCN, WNC, Co, Ni, Pt, W, or a combination thereof, in accordance with some embodiments. The material of the N-type work function metal layer 318N and the P-type work function metal layer 318P may be the same. In some embodiments, the material of the N-type work function metal layer 318N and the P-type work function metal layer 318P are different.

In some embodiments, the N-type work function metal layer 318N is a material such as Ti, Al, Ag, Mn, Zr, TiAl, TiAlC, TaC, TaCN, TaSiN, TaAl, TaAlC, TiAlN, other suitable N-type work function materials, or combinations thereof. For example, the N-type work function metal layer may be deposited utilizing ALD, CVD, or the like. However, any suitable materials and processes may be utilized to form the N-type work function metal layer 318N. In some embodiments, the P-type work function metal layer 318P is a material such as TiN, TaN, Ru, Mo, Al, WN, ZrSi₂, MoSi₂, TaSi₂, NiSi₂, other metal oxides, metal nitrides, metal silicates, transition metal-oxides, transition metal-nitrides, transition metal-silicates, oxynitrides of metals, metal aluminates, zirconium silicate, zirconium aluminate, other suitable P-type work function materials, combinations of these, or the like. Additionally, the P-type work function metal layer 318P may be deposited using a deposition process such as ALD, CVD, or the like, although any suitable deposition process may be used.

In some embodiments, the gate electrode layer 318 may include a single layer or alternatively a multi-layer structure. In some embodiments, the gate electrode layer 318 may further include a capping layer, a barrier layer, and a fill material (not shown). The capping layer may be formed adjacent to the gate dielectric layers 316 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

As discussed above, the dielectric gate structures 308 extend lengthwise in the Y-direction (e.g., parallel to the gate structures 306) to separate the circuit cells 302-1 to 302-6 from each other, as show in FIGS. 4A, 4C, and 4D. Unlike the gate structures 306, however, the dielectric gate structures 308 are not functional gate structures (e.g., do not contain the gate dielectric layer 316 and the gate electrode layer 318). Instead, the dielectric gate structures 308 may be made of electrically insulating materials (e.g., dielectric materials) to provide electrical isolation between various circuit cells. In some embodiments, the dielectric gate structures 308 may be single dielectric layer or multiple layers and selected from a group consisting of SiO₂, SiOC, SiON, SiOCN, carbon content oxide, nitrogen content oxide, carbon and nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, or combinations thereof.

As discussed above, the dielectric gate structures 308 and the gate structures 306 are arranged in the X-direction. In the same row (the row R1 or R2) of the array 300, a gate pitch of the gate structures 306 and a gate pitch of one gate structure 306 to one dielectric gate structure 308 are substantially the same. Furthermore, a gate length of the gate structures 306 in the X-direction and a gate length of the dielectric gate structures 308 in the X-direction are the same. In some embodiments, the gate length of the gate structures 306 is in a range from about 4 nm to about 25 nm.

The array 300 further includes gate end dielectric structures 320 are at ends of the gate structures 306 and the dielectric gate structures 308. More specifically, the gate end dielectric structures 320 are on opposite sides of the gate structures 306 and the dielectric gate structures 308 in the Y-direction, as shown in FIGS. 4A, 4E, and 4F. Further, the gate end dielectric structures 320 extend lengthwise in the X-direction to separate the gate structures 320 and/or the dielectric gate structures 308 aligned in the Y-direction. For example, the gate end dielectric structures 320 separate the gate structures 306-1 and 306-6, as shown in FIGS. 4A and 4E. In some embodiments, the gate end dielectric structures 320 also separate the gate structures 306 and/or the dielectric gate structures 308 from gate structures and/or dielectric gate structures of other circuit cells (not shown) in other rows of the array 300. Furthermore, the gate end dielectric structures 320 extend vertically into the isolation feature 312, as shown in FIGS. 4E and 4F. Therefore, the isolation feature 312 are in contact with sidewalls and bottom surfaces of the gate end dielectric structures 320. The material of the gate end dielectric structures 320 is selected from a group consisting of Si₃N₄, SiON, SiOC, SiOCN, metal content dielectric, high K material (K>=9), or a combination thereof.

The array 300 further include gate spacers 322 similar to gate spacers 212 discussed above. More specifically, the gate spacers 322 are on sidewalls of the gate structures 306 and the dielectric gate structures 308, and over the nanostructures 314, as shown in FIGS. 4C and 4D. The gate spacers 322 are over the nanostructures 314 and on top sidewalls of the gate structures 322 and the dielectric gate structures 308, and thus are also referred to as gate top spacers or top spacers. The gate spacers 322 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 322 may include a single layer or a multi-layer structure.

As shown in FIGS. 4C and 4D, the array 300 further includes inner spacers 324 on the sidewalls of the gate structures 306 and the dielectric gate structures 308, and below the topmost nanostructures 314. Furthermore, the inner spacers 324 are laterally between the source/drain features 326N (or 326P) and the gate structures 306 and between the source/drain features 326N (or 326P) and the dielectric gate structures 308. The inner spacers 324 are also vertically between adjacent nanostructures 314 and between bottommost nanostructures 314 and the substrate 310. The inner spacers 324 may include a dielectric material having higher K value (dielectric constant) than the gate spacers 322 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof. In some embodiments, the gate spacers 322 have a thickness in the X-direction and in a range from about 3 nm to about 12 nm, and the inner spacers 324 have a thickness in the X-direction and in a range from about 3 nm to about 12 nm. In some embodiments, the thickness of the gate spacers 322 in the X-direction and the thickness of the inner spacers 324 in the X-direction are the same. In other embodiments, the thickness of the gate spacers 322 in the X-direction is less than the thickness of the inner spacers 324 in the X-direction due to the gate spacers 322 are trimmed during sequent processes for forming source/drain contacts.

Referring to FIGS. 4C, 4D, and 4F, the array 300 further includes source/drain features 326N and source/drain features 326P over the substrate 310 and in the source/drain regions of the active areas 304. More specifically, the source/drain features 326N and the source/drain features 326P are respectively disposed between the two respective gate structures 306 or one respective gate structure 306 and one respective dielectric gate structure 308. As shown in FIGS. 4C and 4D, the source/drain features 326N are disposed on opposite sides of the respective gate structure 306 in the X-direction to form N-type transistor. Similarly, the source/drain features 326P are disposed on opposite sides of the respective gate structure 306 in the X-direction to form P-type transistor.

Similar to the source/drain features 214 discussed above, the nanostructures 314 extend in the X-direction to connect one source/drain feature 326N/326P to the other source/drain feature 326N/326. More specifically, the source/drain features 326N and the source/drain features 326P are also disposed on opposite sides of the respective nanostructures 314 in the X-direction. Therefore, the source/drain features 326N and the source/drain features 326P are attached and electrically connected to the nanostructures 314 in the X-direction. Further, every two adjacent transistors in the X-direction share one source/drain feature 326N/326P, as shown in FIGS. 4C and 4D.

It is noted that each of the source/drain features 326N and 326P includes a V-shaped top surface in the X-Z cross-sectional view, as shown in FIGS. 4C and 4D. Furthermore, each of the (V-shaped) top surfaces of the source/drain features 326N and 326P has a lowest point that is lower than bottom surfaces of the topmost nanostructures 314, and a highest point that is higher than the bottom surfaces of the topmost nanostructures 314 and lower than top surfaces of the topmost nanostructures 314.

The source/drain features 326N and 326P may be formed by using epitaxial growth. In some embodiments, the source/drain features 326N may include epitaxially-grown material selected from a group consisting of SiP, SiC, SiPC, SiAs, Si, or a combination thereof. In some embodiments, the epitaxially-grown material of the source/drain features 326N may be doped with N-type dopants (such as phosphorus, arsenic, other N-type dopant, or combinations thereof) having a doping concentration in a range from about 2×10¹⁹/cm³ to 8×10²¹/cm³. In some embodiments, the source/drain features 326N for N-type transistors may be respectively referred to as N-type features and N-type source/drain features.

In some embodiments, the source/drain features 326P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 326P may be doped with P-type dopants (such as boron, indium, other P-type dopant, or combinations thereof) having a doping concentration in a range from about 1×10¹⁹/cm³ to 3×10²¹/cm³. In some embodiments, the source/drain features 326P for P-type transistors may be respectively referred to as P-type source/drain features.

Still referring to FIGS. 4C, 4D, and 4F, the array 300 further includes bottom dielectric layers 332 under the source/drain features 326N and 326P and over the substrate 310. In some embodiment, the bottom dielectric layer 332 is in contact with the sidewalls of the inner spacers 324, in the X-Z cross-sectional view, as shown in FIGS. 4C and 4D. In some aspect, the bottom dielectric layer 332 is in contact with and between the inner spacers 324, in the X-Z cross-sectional view. Further, a thickness of the bottom dielectric layers 332 is in a range from about 2 nm to about 10 nm. In some embodiments, the dielectric material of the bottom dielectric layer 332 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), other suitable material(s), or combinations thereof, and may be deposited by CVD, PVD, ALD, HDPCVD, MOCVD, RPCVD, PECVD, LPCVD, ALCVD, APCVD, other suitable methods, or combinations thereof. It should be noted that the source/drain features 326N and 326P are separated from the substrate 310 by the bottom dielectric layers 332. As such, it prevents the leakage current of the resultant transistors from one source/drain feature 326N/326P to another source/drain feature 326N/326P through the substrate 310, thereby improving performances of the resultant transistors.

Still referring to FIGS. 4C, 4D, and 4F, the array 300 further includes silicide features 328 over and in contact with the source/drain features 326N and 326P. In some embodiment, the silicide feature 328 is between the adjacent two gate structures 306 in the X-direction. As shown in FIGS. 4C and 4D, each of the silicide features 328 has a V-shape in the X-Z cross-sectional view. The silicide features 328 may also be referred to as V-shaped silicide features. In other embodiments, each of the silicide features 328 has a U-shape in the X-Z cross-sectional view (and the source/drain features 326N and 326P each includes a U-shaped top surface in the X-Z cross-sectional view). More specifically, each of the silicide features 328 has a V-shaped top surface and a V-shaped bottom surface in the X-Z cross-sectional view, as shown in FIGS. 4C and 4D.

In some embodiments, the silicide features 328 extend lower than the bottom surfaces of the topmost nanostructures 314. More specifically, each of the (V-shaped) bottom surfaces of the silicide features 328 has a lowest point that is lower than the bottom surfaces of the topmost nanostructures 314. In some embodiments, the lowest points of the (V-shaped) bottom surfaces of the silicide features 328 are about 1 nm to about 15 nm lower than the bottom surfaces of the topmost nanostructures 314. In addition, each of the (V-shaped) bottom surfaces of the silicide features 328 has a highest point that is higher than the bottom surfaces of the topmost nanostructures 314 and lower than the top surfaces of the topmost nanostructures 314. Further, each of the (V-shaped) top surfaces of the silicide features 328 has a lowest point that is lower than the top surfaces of the topmost nanostructures 314 and higher than the bottom surfaces of the topmost nanostructures 314, and a highest point that is higher than higher than the top surfaces of the topmost nanostructures 314. As such, each of the silicide features 328 is in contact with the sidewalls of the gate spacers 322 and the topmost nanostructures 314 in the X-direction, as shown in FIGS. 4C and 4D. In some aspect, each of the silicide features 328 is in contact with and between the gate spacers 322, in the X-Z cross-sectional view.

In some aspects, as shown in FIGS. 4C and 4D, a shortest distance DS from the silicide features 328 to the substrate 310 in the Z-direction is less than a distance DN from the bottom surfaces of the topmost nanostructures 314 to the substrate 310 in the Z-direction. Furthermore, a longest distance DL from the silicide features 328 to the substrate 310 in the Z-direction is greater than the distance from the bottom surfaces of the topmost nanostructures 314 to the substrate 310 in the Z-direction.

The silicide features 328 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. In some embodiments, the silicide features 328 over the source/drain features 326N and the silicide features 328 over the source/drain features 326P have different material. For example, the silicide features 328 over the source/drain features 326N include TiSi and the silicide features 328 over the source/drain features 326P include silicide material selected from a group consist of PtSi, NiSi, CoSi, or MoSi.

Referring to FIGS. 4A, 4B, 4C, 4D, and 4F, the array 300 further includes three types of source/drain contacts, source/drain contacts 330A, source/drain contacts 330B, and the source/drain contacts 330C (may be collectively referred to as the source/drain contacts 330), over and in contact with the silicide features 328, and electrically connected to the silicide features 328 and the source/drain features 326N and 326P. The source/drain contacts 330A, 330B, and 330C extend lengthwise the Y-direction. As shown in FIGS. 4A, 4C, 4D and 4F, the source/drain contacts 330A each is disposed over and in contact with one source/drain feature 326N or 326P. The source/drain contacts 330B each is directly disposed over and in contact with one source/drain feature 326N and one source/drain feature 326P in the same circuit cell. The source/drain contacts 330C each is disposed over and in contact with two source/drain features 326N or 326P in two circuit cells in adjacent two rows of the array 300.

More specifically, as shown in FIG. 4A, the source/drain contacts 330C includes source/drain contacts 330B-1, 330B-2, and 330B-3. The source/drain contacts 330B-1 and 330B-2 each is disposed over and in contact with one source/drain feature 326P in the circuit cell 302-1 in the row R1 and one source/drain feature 326P in the circuit cell 302-4 in the row R2. The source/drain contact 330B-3 is disposed over and in contact with one source/drain feature 326P in the circuit cell 302-3 in the row R1 and one source/drain feature 326P in the circuit cell 302-6 in the row R2. The source/drain contacts 330B each is shared by the circuit cells in adjacent two rows of the array 300. Therefore, in some embodiments, the source/drain contacts 330B may also be referred to as shared source/drain contacts.

In some embodiments, some of the source/drain contacts are in contact with the dielectric structures 320. For example, as shown in FIGS. 4A and 4F, a sidewall and a bottom surface of the source/drain contact 330A is in contact with the dielectric structure 320. In some embodiments, the source/drain contacts 330B extend in the Y-direction to overlap the cell boundaries (e.g., the cell boundaries MC1 to MC6 discussed above) of the circuit cells in a top view, as shown in FIGS. 4A and 4B. The source/drain contacts 330B are also in contact with the dielectric structure 320, in accordance with some embodiments.

As shown in FIGS. 4C and 4D, top surfaces of the source/drain contacts 330 are substantially level with top surfaces of the gate structures 306. The top surfaces of the source/drain contacts 330 are planar. In other words, each of the source/drain contacts 330 has a planar top surface that is level with top surfaces of the gate structure 306. Furthermore, each of the bottom surfaces of the source/drain contacts 330 has a V-shape in the X-Z cross-sectional view, as shown in FIGS. 4C and 4D. In other words, each of the source/drain contacts 330 has a V-shaped bottom surface in the X-Z cross-sectional view. In some embodiments, each of the source/drain contacts 330 has a U-shape bottom surface in the X-Z cross-sectional view (and each of the silicide features 328 has a U-shape in the X-Z cross-sectional view). In some embodiments, lowest points of the (V-shaped) bottom surfaces of the source/drain contacts 330 are about 1 nm to about 10 nm lower than the top surfaces of the topmost nanostructures 314.

The source/drain contacts 330 may each include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 330 may each include single conductive material layer or multiple conductive layers.

The source/drain contacts 330 are extended and enlarged to have V-shaped bottom surfaces. Therefore, the resistance of the source/drain contacts 330 are reduced. Further, vertical sidewall length of the source/drain contacts 330 are not extended and the top surfaces of the source/drain contacts 330 are substantially level with top surfaces of the gate structures 306. As such, the contact-to-gate parasitic capacitance is reduced. Furthermore, due to the V-shaped bottom surfaces of the source/drain contacts 330 and the V-shaped top surfaces of the silicide features 328 as well as the V-shaped bottom surfaces of the silicide features 328 and the V-shaped top surfaces of the source/drain features 326N/326P, the contact area between the source/drain contacts 330 and the silicide features 328 as well as between the silicide features 328 and the source/drain features 326N/326P are increased, thereby reducing the contact resistance between the source/drain contacts 330 and the silicide features 328 as well as between the silicide features 328 and the source/drain features 326N/326P. Therefore, the performance of the transistors in the array 300 are improved.

Referring to FIGS. 4C to 4F, the array 300 further includes a cap layer 333, an inter-layer dielectric (ILD) layer 334, and an inter-metal dielectric (IMD) layer 336. The cap layer 333 is over the gate structures 306 for protecting the gate structures 306. In some embodiments, the cap layer 333 includes silicon nitride (Si₃N₄). The ILD layer 334 is over the substrate 310, the isolation feature 312, the gate structures 306, the dielectric gate structure 308, the source/drain contacts 330, and the cap layer 333, between the source/drain features 326N/326P, and between the source/drain contacts 330. The IMD layer 336 is over the ILD layer 334, the gate structures 306, the dielectric gate structure 308, the source/drain contacts 330, and the cap layer 333.

The ILD layer 334 and the IMD layer 336 include a dielectric material including, for example, silicon oxide, silicon nitride, silicon oxynitride, TEOS-formed oxide, PSG, BPSG, low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, other low-k dielectric material, or combinations thereof. In some embodiments, the ILD layer 334 and the IMD layer 336 are a dielectric layer that includes a low-k dielectric material (generally referred to as a low-k dielectric layer). The ILD layer 334 and the IMD layer 336 may include a multilayer structure having multiple dielectric materials.

Referring to FIGS. 4B to 4F, the array 300 further includes gate vias VG, vias VD, and metal layers M1. The gate vias VG and vias VD are disposed in the ILD layer 334 and the metal layers M1 are disposed in the IMD layer 336. The metal layers M1 are over and electrically connected to respective gate structures 306 and respective source/drain contacts 330. The gate vias VG are over and in contact with the gate structures 306 and electrically connect the gate structures 306 to respective metal layers M1. The vias VD are over and in contact with the source/drain contacts 330 and electrically connect the source/drain contacts 330 to respective metal layers M1. The materials of the gate vias VG, the vias VD, and the metal layers M1 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

As shown in FIG. 4B to 4F, the metal layers M1 extend in the X-direction and further include metal layers MN, VM1, VM2, and VM3. The metal layers MN are disposed within the cell boundaries (e.g., the cell boundaries MC1 to MC6 of the circuit cells 302-1 to 302-6) in the top view, as shown in FIG. 4B. The metal layers VM1, VM2, and VM3 are disposed overlap (or across) the cell boundaries (e.g., the cell boundaries MC1 to MC6 of the circuit cells 302-1 to 302-6) in the top view, as shown in FIG. 4B. In some embodiments, a width of the metal layers VM1, VM2, and VM3 in the Y-direction is greater than a width of the metal layers MN in the Y-direction.

The metal layers M1 are respectively connected to respective gate structures 306 and respective source/drain contacts 330 through respective gate vias VG and VD. In some embodiments, the gate vias VG, VD and metal layers M1 are used to construct connections of the transistors in the circuit cells 302-1 to 302-6. In some embodiments, the vias VD and metal layers M1 are connected to power sources or voltage sources (not shown) to provide voltage (VDD or VSS) to the transistors in the circuit cells 302-1 to 302-6. In the present embodiment, the metal layers VM1 and VM3 are connected to a VSS power source (not shown) and the metal layer VM2 is connected to a VDD power source (not shown). Therefore, the metal layer VM2 may be also referred to as the (VDD) power metal line, the (VDD) power line, or (VDD) power conductor, and the metal layers VM1 and VM3 may be also referred to as the (VSS) power metal line, the (VSS) power line, or (VSS) power conductor.

As shown in FIG. 4B, the vias VD which electrically connected to the metal layer VM2 have a larger via size than other vias VD and gate vias VG, in accordance with some embodiments. Therefore, due to small resistances of larger size vias VD, the transistors in the circuit cells 302-1 to 302-6 may be provided with voltage (or power) with low voltage drop, thereby improving the performance of the array 300. Further, the top surfaces of the source/drain contacts 330 are substantially level with bottom surfaces of the gate vias VG. As such, there is no contact-to-via parasitic capacitance between the source/drain contacts 330 and the gate vias VG in the X-direction, thereby improving the performance of the array 300.

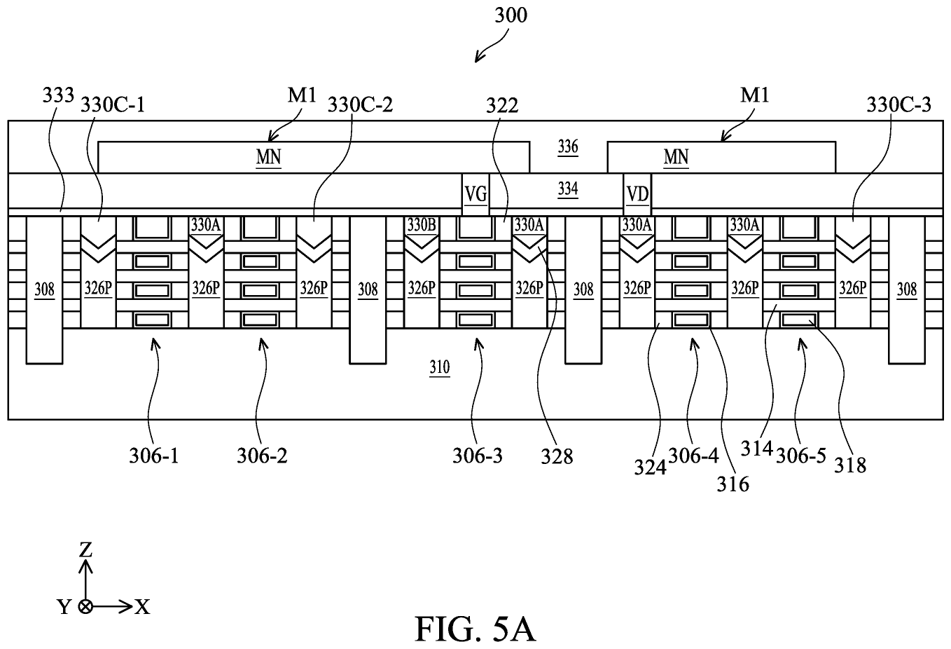

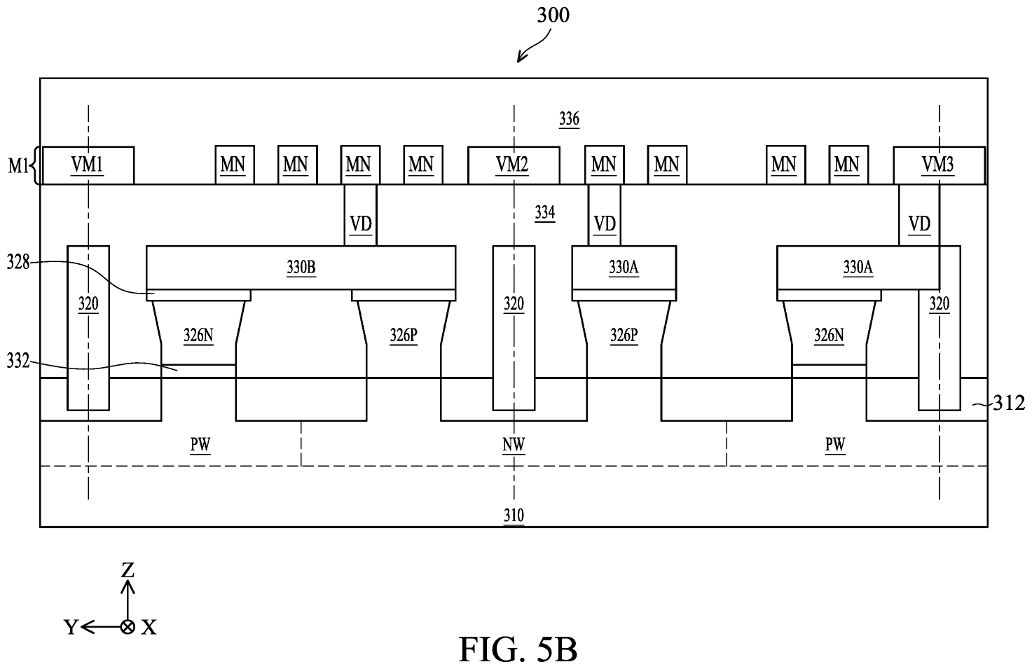

FIG. 5A illustrates an X-Z cross-sectional view of the array 300 of the circuit cells along a line D-D′ in FIGS. 4A and 4B, in accordance with some alternative embodiments of the present disclosure. FIG. 5B illustrates a Y-Z cross-sectional view of the array of the circuit cells along a line F-F′ in FIGS. 4A and 4B, in accordance with some alternative embodiments of the present disclosure. As discussed above, the bottom dielectric layers 332 are under the source/drain features 326N and 326P, as shown in FIGS. 4C, 4D, and 4F. In some alternative embodiments, the bottom dielectric layers 332 are formed under the source/drain features 326N and the source/drain features 326P are formed in contact with the substrate 310, as shown in FIGS. 5A and 5B. Therefore, each of the source/drain features 326P has a larger volume than the source/drain features 326N to keep strain for nanostructures 314 in the P-type transistor, thereby improving the performance of the P-type transistor in the array 300.

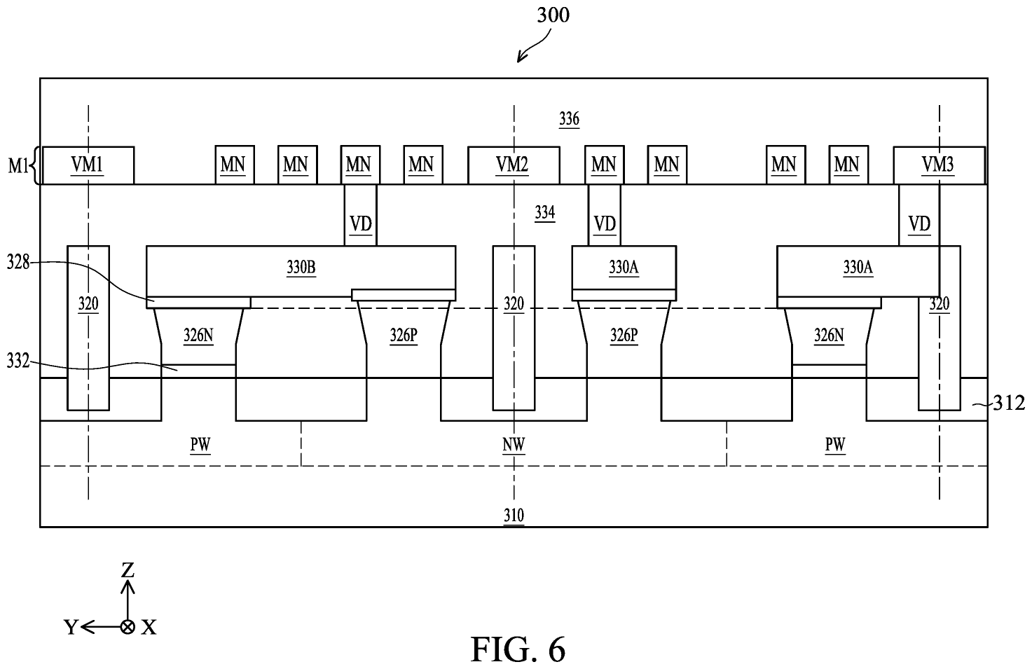

FIG. 6 illustrates a Y-Z cross-sectional view of the array 300 of the circuit cells along a line F-F′ in FIGS. 4A and 4B, in accordance with some alternative embodiments of the present disclosure. Referring back to FIGS. 4F, the bottom surfaces of the source/drain contacts 330 are substantially level with each other. In some alternative embodiments, as shown in FIG. 6, the bottom surfaces of the source/drain contacts 330 over the source/drain features 326N are lower than the bottom surfaces of the source/drain contacts 330 over the source/drain features 326P. Furthermore, for the source/drain contacts 330B, a bottom surface of a portion of the source/drain contact 330B that is over the source/drain feature 326N is lower than a bottom surface of a portion of the source/drain contact 330B that is over the source/drain feature 326P, as shown in FIG. 6.

Therefore, the source/drain contacts 330 over the source/drain features 326N and the source/drain contacts 330 over the source/drain features 326N and 326P are larger than the source/drain contacts 330 over the source/drain feature 326P to have lower resistance. Furthermore, as shown in FIG. 6, each of the source/drain features 326P has a larger volume than the source/drain features 326N to keep strain for nanostructures 314 in the P-type transistor, thereby improving the performance of the P-type transistor in the array 300.

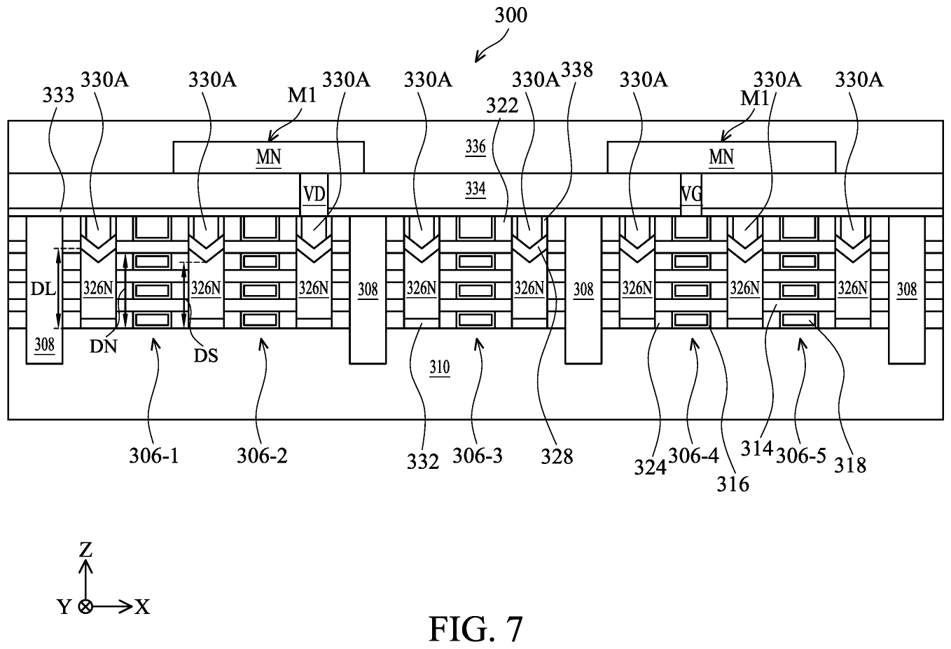

FIG. 7 illustrates an X-Z cross-sectional view of the array 300 of the circuit cells along a line C-C′ in FIGS. 4A and 4B, in accordance with some alternative embodiments of the present disclosure. Referring back to FIGS. 4C and 4D, the source/drain contacts 330 are also between and in contact with the gate spacers 322 in the X-direction. In some alternative embodiments, as shown in FIG. 7, the array 300 further includes contact sidewall dielectric layers 338 on sidewalls of the source/drain contacts 330 to separate the source/drain contacts 330 from the gate spacers 322 in the X-direction. More specifically, the contact sidewall dielectric layers 338 fully surround (sidewalls of) the source/drain contacts 330. In some aspects, the contact sidewall dielectric layers 338 are in contact with sidewalls of the gate spacers 322, as shown in FIG. 7.

Each of the contact sidewall dielectric layers 338 has a thickness in the X-direction or Y-direction and in a range from about 1 nm to about 5 nm. In some embodiments, the contact sidewall dielectric layers 338 include dielectric material having nitrogen-content, and the dielectric material selected from a group consist of Si₃N₄, SiON, SiOC, SiOCN, or a combination thereof. The contact sidewall dielectric layers 338 may further improve the isolation margin for the source/drain contacts 330 to the gate structures 306. Therefore, the contact-to-gate parasitic capacitance is reduced, thereby improving the performance of the array 300.

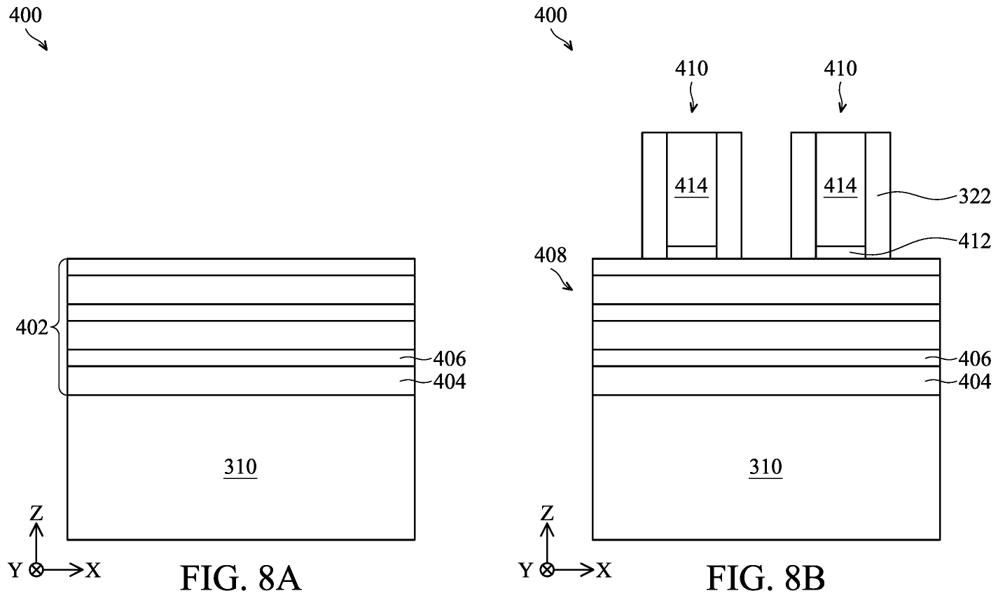

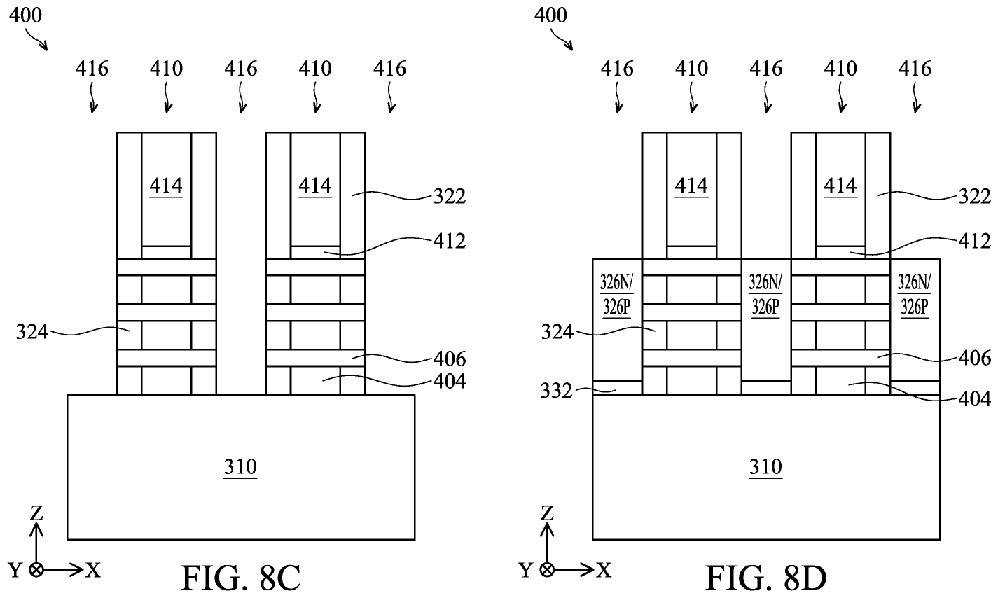

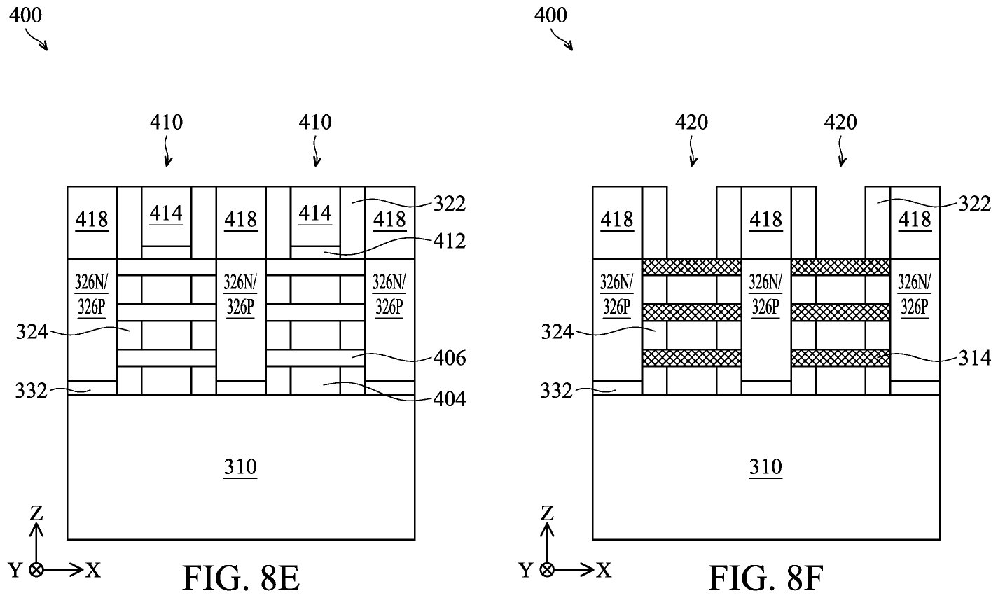

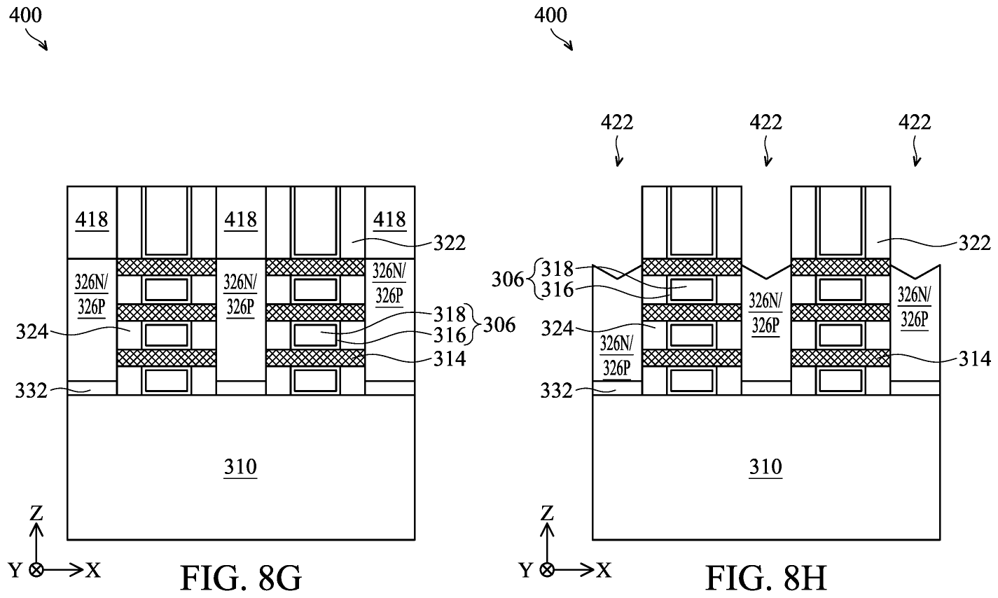

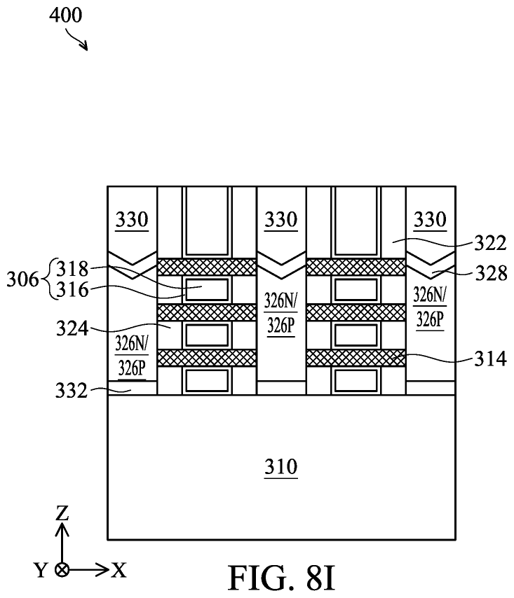

FIGS. 8A to 8I are cross-sectional views of a device 400 at various fabrication stages, which show exemplary fabrication of transistors with V-shaped silicide features discussed above, in accordance with some embodiments of the present disclosure. Referring to FIG. 8A, a stack 402 is formed over the substrate 310. In some embodiments, the substrate 310 may include one or more well regions, such as n-type well regions (e.g., the n-type well NW discussed above) doped with an n-type dopant (i.e., phosphorus (P) or arsenic (As)) or p-type well regions (e.g., the p-type well PW discussed above) doped with a p-type dopant (i.e., boron (B)), for forming different types of devices. The doping the n-type wells and the p-type wells may be formed using ion implantation or thermal diffusion.

The stack 402 includes semiconductor layers 404 and 406, and the semiconductor layers 404 and 406 are alternatingly stacked in the Z-direction. The semiconductor layers 404 and the semiconductor layers 406 may have different semiconductor compositions. In some embodiments, semiconductor layers 404 are formed of silicon germanium (SiGe) and the semiconductor layers 406 are formed of silicon (Si). In these embodiments, the additional germanium content in the semiconductor layers 404 allow selective removal or recess of the semiconductor layers 404 without substantial damages to the semiconductor layers 406, so that the semiconductor layers 404 are also referred to as sacrificial layers. In some embodiments, the semiconductor layers 404 and 406 are epitaxially grown over (on) the substrate 302 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 404 and the semiconductor layers 406 are deposited alternatingly, one-after-another, to form the stack 402.

It should be noted that three (3) layers of the semiconductor layers 404 and three (3) layers of the semiconductor layers 406 are alternately and vertically arranged (or stacked) as shown in FIG. 8A, which are for illustrative purposes only and not intended to be limiting beyond what is specifically recited in the claims.

Referring to FIG. 8B, after the formation of the stack 402, the stack 402 is then patterned to form fins 408 over the substrate 310. Although not shown in FIG. 8B, after the formation of the fins 408, the isolation feature 312 discussed is then formed over the substrate 302 and between the fins 408.

Still referring to FIG. 8B, dummy gate structures 410 are formed over the fins 408. In some embodiments, to form the dummy gate structures 410, a dummy interfacial material for dummy interfacial layers 412 is first formed over fins 408. In some embodiments, the dummy interfacial layer 412 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material for dummy gate electrodes 414 is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or a combination thereof. The dummy gate material and/or the dummy interfacial material may be formed by way of a thermal oxidation process and/or a deposition process (e.g., physical vapor deposition (PVD), CVD, PECVD, and ALD).

After the formation of the dummy interfacial material and the dummy gate material, one or more etching processes may be performed to pattern the dummy gate material for the dummy gate electrodes 414 and the dummy interfacial material for the dummy interfacial layers 412, thereby forming the dummy gate structures 410 each having the dummy interfacial layer 412 and the dummy gate electrode 414. The dummy interfacial layers 412 may also be referred to as dummy gate dielectrics. The dummy gate structures 410 may undergo a gate replacement process through subsequent processing to form metal gates, such as a high-k metal gate, as discussed in greater detail below.

Still referring to FIG. 8B, after the formation of the dummy gate structures 410, gate spacers 322 are formed on sidewalls of the dummy gate structures 410 and over the top surfaces of the fins 408. More specifically, the gate spacers 322 are formed on opposite sidewalls of the dummy gate structures 410. In some embodiments, the gate spacers 322 may be formed by conformally depositing a spacer layer (containing the dielectric material) over the fins 408 and dummy gate structures 410, followed by an anisotropic etching process to remove top portions of the spacer layer from the top surfaces of the fins 408 and dummy gate structures 410. After the etching process, portions of the spacer layer on the sidewall surfaces of the fins 408 and the dummy gate structures 410 substantially remain and become the gate spacers 322. In some embodiments, the anisotropic etching process is a dry (e.g., plasma) etching process. Additionally or alternatively, the formation of the gate spacers 322 may also involve chemical oxidation, thermal oxidation, ALD, CVD, and/or other suitable methods. The gate spacers 322 may also be interchangeably referred to as top spacers

Referring to FIG. 8C, the fins 408 are recessed to form source/drain trenches 416 in the fins 408 (or passing through the semiconductor layers 404 and 406). Specifically, the source/drain trenches 416 may be formed by performing one or more etching processes to remove portions of the semiconductor layers 404, the semiconductor layers 406 that do not vertically overlap or be covered by the dummy gate structures 410 and the gate spacers 322. In some embodiments, a single etchant may be used to remove the semiconductor layers 404 and the semiconductor layers 406, whereas in other embodiments, multiple etchants may be used to perform the etching process.

Still referring to FIG. 8C, the inner spacers 324 are formed under the gate spacers 322 and between the semiconductor layers 406 as well as between the semiconductor layers 406 and the substrate 302. In formation of the inner spacers 324, side portions of the semiconductor layers 404 are removed via a selective etching process. Specifically, the selective etching process is performed that selectively etches the side portions of the semiconductor layers 404 under the gate spacers 322 through the source/drain trenches 416, with minimal (or no) etching of semiconductor layers 406, such that gaps are formed between the semiconductor layers 406 as well as between the semiconductor layers 406 and the substrate 302. The etching process is configured to laterally etch (e.g., in the first direction) the semiconductor layers 404 below the gate spacers 322. The selective etching process is a dry etching process, a wet etching process, another suitable etching process, or a combination thereof.

Still referring to FIG. 8C, the inner spacers 324 are then formed to fill the gaps. In some embodiments, sidewalls of the inner spacers 324 are aligned to sidewalls of the gate spacers 322 and the semiconductor layers 406, as shown in FIG. 8C. In order to form the inner spacers 324, a deposition process forms a spacer layer into the source/drain trenches 416 and the gaps, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 416. The deposition process is configured to ensure that the spacer layer fills the gaps between the semiconductor layers 406 as well as between the semiconductor layer 406 and the substrate 310 under the gate spacers 322. An etching process is then performed that selectively etches the spacer layer to form inner spacers 324 (as shown in FIG. 8C) with minimal (to no) etching of the semiconductor layer 406, the substrate 310, the dummy gate structures 410, and the gate spacers 322.

Referring to FIG. 8D, the bottom dielectric layers 332 and the source/drain features 326N/326P over the bottom dielectric layers 332 discussed above are formed in the source/drain trenches 416. One or more epitaxy processes may be employed to grow the source/drain features 326N/326P. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. One or more annealing processes may be performed to activate the dopants in the source/drain features 326N/326P. The annealing processes may include rapid thermal annealing (RTA) and/or laser annealing processes.

Referring to FIG. 8E, an interlayer dielectric (ILD) layer 418 is formed to fill the space between the gate spacers 322. The ILD layer 418 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 418 may be formed by PECVD (plasma enhanced CVD), FCVD (flowable CVD), or other suitable methods. Subsequent to the formation of the ILD layer 418, a CMP process and/or other planarization process is performed on the ILD layer 418 until the top surfaces of the dummy gate structures 410 are exposed.

In some embodiments, before the formation of the ILD layer 418, a contact etch stop layer (CESL) may be conformally formed on the sidewalls of the gate spacers 322 and over the top surfaces of the source/drain features 312N/312P. The ILD layer 418 is then formed over and between the CESL to fill the space between the CESL. The CESL includes a material that is different than the ILD layer 418. The CESL may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods.

Referring to FIG. 8F, the dummy gate structures 410 are selectively removed through any suitable lithography and etching processes. In some embodiments, the lithography process may include forming a photoresist layer (resist), exposing the resist to a pattern, performing a post-exposure bake process, and developing the resist to form a masking element, which exposes a region including the dummy gate structures 410. Then, the dummy gate structures 410 are selectively etched through the masking element. Etch selectivity may be achieved by selecting the appropriate etching chemicals, and the dummy gate structures 410 may be removed without substantially affecting the gate spacers 322, the inner spacers 324, and the substrate 310. The removal of the dummy gate structures 410 creates gate trenches 420. The gate trenches 420 expose the top surfaces of the topmost semiconductor layers 406 underlies the dummy gate structures 410.

Still referring to FIG. 8F, the semiconductor layers 404 are selectively removed through the gate trenches 420, using a wet or dry etching process for example, so that the semiconductor layers 406 are exposed in the gate trenches 420 to form the nanostructures 314 discussed above. Such a process may also be referred to as a wire release process, a nanowire release process, a nanosheet release process, a nanowire formation process, a nanosheet formation process, or a wire formation process. In some embodiments, the removal of the semiconductor layers 404 causes the exposed semiconductor layers 406 (the nanostructures 314) to be spaced apart from each other in the vertical direction (e.g., in the Z-direction). The exposed semiconductor layers 406 extend longitudinally in the horizontal direction (e.g., in the X-direction), and each connects one source/drain feature 312N/312P to another source/drain feature 312N/312P.

Referring to FIG. 8G, the gate structures 306 discussed above are formed in the gate trenches 420. The gate structures 306 each includes the gate dielectric layer 316 and the gate electrode 318 over the gate dielectric layer 316, as discussed above. In some embodiments, the gate dielectric layers 316 are formed to wrap around wrap around each of the nanostructures 314. Additionally, the gate dielectric layers 316 are also formed on sidewalls of the inner spacers 324 and the gate spacers 322.

The gate electrodes 318 are then formed to fill the remaining spaces of the gate trenches 420, and over the gate dielectric layers 316 in such a way that the gate electrodes 318 each wraps around the nanostructures 310, the gate dielectric layer 316, and the interfacial layers (if present). The gate electrodes 318, the gate dielectric layers 316, and the interfacial layers (if present) may be collectively called as the gate structures 306 wrapping around the nanostructures 314, as discussed above.

Referring to FIG. 8H, the ILD layer 418 and portions of source/drain features 326N/326P are recessed to form contact openings 422. Specifically, the contact openings 422 may be formed by performing one or more etching processes to remove the ILD layer 418 over the source/drain features 326N/326P and portions of the source/drain features 326N/326P. The contact openings 422 expose the top surfaces of the source/drain features 326N/326P for subsequent silicide features 328 and source/drain contact 330 formation. In is noted that the portions of the source/drain features 326N/326P are remove to form the V-shaped top surfaces of the source/drain features 326N/326P discussed above. Additional processes are performed before or during the formation of the contact openings 422 to form the V-shaped top surfaces of the source/drain features 326N/326P. For example, a polymer layer may be formed before or during the formation of the contact openings 422 to make the one or more etching processes have different etching rates on various locations to be recessed, thereby forming the V-shaped top surfaces of the source/drain features 326N/326P.

Referring to FIG. 8I, the silicide features 328 and the source/drain contacts 330 discussed above are formed over the source/drain features 326N/326P and in the contact openings 422. Due to the V-shaped top surfaces of the source/drain features 326N/326P, the silicide features 328 are formed with the V-shape and the source/drain contacts 330 are formed with the V-shaped bottom surfaces, as discussed above. As such, the device 400 is completely formed to have transistors with the V-shape silicide features 328 for presenting the exemplary fabrication of the transistor in the circuit cells 302-1 to 302-6 discussed above.

The embodiments disclosed herein relate to semiconductor structures, and more particularly to semiconductor devices comprising V-shaped silicide features for the transistors in the circuit cells, such that source/drain contacts are enlarged to have V-shaped bottom surfaces. Furthermore, the present embodiments provide one or more of the following advantages. The enlarged source/drain contacts for the transistors provides lower resistance, which improves the performance of the circuit cells, such as circuit speed. Furthermore, each of the enlarged source/drain contacts has a top surface that is level with the top surfaces of the gate structures and the bottom surfaces of the gate vias, such that contact-to-gate parasitic capacitances and contact-to-via parasitic capacitances are reduced, thereby improving the performance of the circuit cells.

Thus, one of the embodiments of the present disclosure describes a semiconductor device that includes circuit cells having transistors. Each of the transistors includes nanostructures vertically stacked from each other in a Z-direction, a gate structure wrapping around the nanostructures and extending in a Y-direction, and source/drain features on opposite sides of the gate structure in an X-direction. The semiconductor device further includes silicide features over and in contact with the source/drain features. The silicide features extend lower than bottom surfaces of topmost nanostructures of the nanostructures. The semiconductor structure further includes source/drain contacts over and in contact with the silicide features. Each of bottom surfaces of the source/drain contacts has a V-shape in an X-Z cross-sectional view.

In some embodiments, the silicide features are V-shaped silicide features in the X-Z cross-sectional view.

In some embodiments, each of top surfaces of the silicide features has a lowest point lower than top surfaces of the topmost nanostructures of the nanostructures and higher than the bottom surfaces of the topmost nanostructures of the nanostructures.

In some embodiments, each of top surfaces of the silicide features has a highest point higher than top surfaces of the topmost nanostructures of the nanostructures.

In some embodiments, top surfaces of the source/drain contacts are substantially level with top surfaces of the gate structures.

In some embodiments, the source/drain contacts includes first source/drain contacts over N-type source/drain features of the source/drain features, and second source/drain contacts over P-type source/drain features of the source/drain features. Bottom surfaces of the first source/drain contacts are lower than bottom surfaces of the second source/drain contacts.

In some embodiments, the semiconductor device further includes dielectric layers on sidewalls of the source/drain contacts.

In some embodiments, the semiconductor device further includes dielectric structures on opposite sides of the gate structures in the Y-direction. One of the source/drain contacts is in contact with one of the dielectric structures.

In some embodiments, the semiconductor device further includes bottom dielectric layers under the source/drain features.

In some embodiments, a thickness of the bottom dielectric layers is in a range from about 2 nm to about 10 nm.

In another of the embodiments, discussed is a semiconductor device including a substrate, first nanostructures, second nanostructures, a gate structure, N-type source/drain features, P-type source/drain features, silicide features, and source/drain contacts. The first nanostructures are vertically stacked over the substrate from each other in a Z-direction. The second nanostructures are vertically stacked over the substrate from each other in the Z-direction. The gate structure wraps around the first nanostructures and the second nanostructures and extending in a Y-direction. The N-type source/drain features are attached to the first nanostructures in an X-direction. The P-type source/drain features are attached to the second nanostructures in the X-direction. The silicide features are over and in contact with the N-type source/drain features and the P-type source/drain features. Each of the silicide features has a V-shape in an X-Z cross-sectional view. Lowest points of bottom surfaces of the silicide features are lower than bottom surfaces of topmost nanostructures of the first nanostructures and the second nanostructures. The source/drain contacts are over and in contact with the silicide features.

In some embodiments, the lowest points of the bottom surfaces of the silicide features are about 1 nm to about 15 nm lower than the bottom surfaces of the topmost nanostructures.

In some embodiments, each of the source/drain contacts includes a planar top surface level with a top surface of the gate structure, and a V-shaped bottom surface in the X-Z cross-sectional view.

In some embodiments, one of the source/drain contacts is directly over one of the N-type source/drain features and one of the P-type source/drain features. A bottom surface of a first portion of the one of the source/drain contacts over the one of the N-type source/drain features is lower than a bottom surface of a second portion of the one of the source/drain contacts over the one of the P-type source/drain features.

In some embodiments, the semiconductor device further includes bottom dielectric layers under the N-type source/drain features and the P-type source/drain features.

In some embodiments, the semiconductor device further includes bottom dielectric layers under the N-type source/drain features. The P-type source/drain features are in contact with the substrate.

In yet another of the embodiments, discussed is a semiconductor device that includes a substrate, an N-type transistor and a P-type transistor over the substrate, first source/drain features, second source/drain features, silicide features, and source/drain contacts. The N-type transistor and the P-type transistor share a gate structure extending in a Y-direction. The first source/drain features are on opposite sides of nanostructures of the N-type transistor in an X-direction. The second source/drain features are on opposite sides of nanostructures of the P-type transistor in the X-direction. The silicide features are over and in contact with the first source/drain features and the second source/drain features. A shortest distance from the silicide features to the substrate in a Z-direction is less than a distance from bottom surfaces of topmost nanostructures of the nanostructures of the N-type transistor and the P-type transistor to the substrate in the Z-direction. The source/drain contacts are over and in contact with the silicide features.

In some embodiments, a longest distance from the silicide features to the substrate in the Z-direction is greater than the distance from the bottom surfaces of the topmost nanostructures of the nanostructures of the N-type transistor and the P-type transistor to the substrate in the Z-direction.

In some embodiments, the semiconductor device further includes a gate via over and in contact with the gate structure. Top surfaces of the source/drain contacts are substantially level with a bottom surface of the gate via.

In some embodiments, each of the source/drain contacts has a V-shaped bottom surface in an X-Z cross-sectional view. Lowest points of the V-shaped bottom surfaces are about 1 nm to about 10 nm lower than top surfaces of the topmost nanostructures of the nanostructures of the N-type transistor and the P-type transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
circuit cells having transistors, wherein each of the transistors comprises:
nanostructures vertically stacked from each other in a Z-direction;
a gate structure wrapping around the nanostructures and extending in a Y-direction;
source/drain features on opposite sides of the gate structure in an X-direction;
silicide features over and in contact with the source/drain features, wherein the silicide features extend lower than bottom surfaces of topmost nanostructures of the nanostructures; and
source/drain contacts over and in contact with the silicide features, wherein each of bottom surfaces of the source/drain contacts has a V-shape in an X-Z cross-sectional view.

2. The semiconductor device of claim 1, wherein the silicide features are V-shaped silicide features in the X-Z cross-sectional view.

3. The semiconductor device of claim 2, wherein each of top surfaces of the silicide features has a lowest point lower than top surfaces of the topmost nanostructures of the nanostructures and higher than the bottom surfaces of the topmost nanostructures of the nanostructures.

4. The semiconductor device of claim 2, wherein each of top surfaces of the silicide features has a highest point higher than top surfaces of the topmost nanostructures of the nanostructures.

5. The semiconductor device of claim 1, wherein top surfaces of the source/drain contacts are substantially level with top surfaces of the gate structures.

6. The semiconductor device of claim 1, wherein the source/drain contacts comprise:
first source/drain contacts over N-type source/drain features of the source/drain features; and
second source/drain contacts over P-type source/drain features of the source/drain features,
wherein bottom surfaces of the first source/drain contacts are lower than bottom surfaces of the second source/drain contacts.

7. The semiconductor device of claim 1, further comprising:
dielectric layers on sidewalls of the source/drain contacts.

8. The semiconductor device of claim 1, further comprising:
dielectric structures on opposite sides of the gate structures in the Y-direction, wherein one of the source/drain contacts is in contact with one of the dielectric structures.

9. The semiconductor device of claim 1, further comprising:
bottom dielectric layers under the source/drain features.

10. The semiconductor device of claim 9, wherein a thickness of the bottom dielectric layers is in a range from about 2 nm to about 10 nm.

11. A semiconductor device, comprising:
a substrate;
first nanostructures vertically stacked over the substrate from each other in a Z-direction;
second nanostructures vertically stacked over the substrate from each other in the Z-direction;
a gate structure wrapping around the first nanostructures and the second nanostructures and extending in a Y-direction;
N-type source/drain features attached to the first nanostructures in an X-direction;
P-type source/drain features attached to the second nanostructures in the X-direction;
silicide features over and in contact with the N-type source/drain features and the P-type source/drain features, wherein each of the silicide features has a V-shape in an X-Z cross-sectional view, wherein lowest points of bottom surfaces of the silicide features are lower than bottom surfaces of topmost nanostructures of the first nanostructures and the second nanostructures; and
source/drain contacts over and in contact with the silicide features.

12. The semiconductor device of claim 11, wherein the lowest points of the bottom surfaces of the silicide features are about 1 nm to about 15 nm lower than the bottom surfaces of the topmost nanostructures.

13. The semiconductor device of claim 11, wherein each of the source/drain contacts comprises:
a planar top surface level with a top surface of the gate structure; and
a V-shaped bottom surface in the X-Z cross-sectional view.

14. The semiconductor device of claim 11, wherein one of the source/drain contacts is directly over one of the N-type source/drain features and one of the P-type source/drain features,
wherein a bottom surface of a first portion of the one of the source/drain contacts over the one of the N-type source/drain features is lower than a bottom surface of a second portion of the one of the source/drain contacts over the one of the P-type source/drain features.

15. The semiconductor device of claim 11, further comprising:
bottom dielectric layers under the N-type source/drain features and the P-type source/drain features.

16. The semiconductor device of claim 11, further comprising:
bottom dielectric layers under the N-type source/drain features, wherein the P-type source/drain features are in contact with the substrate.

17. A semiconductor device, comprising:
a substrate;
an N-type transistor and a P-type transistor over the substrate, wherein the N-type transistor and the P-type transistor share a gate structure extending in a Y-direction;
first source/drain features on opposite sides of nanostructures of the N-type transistor in an X-direction;
second source/drain features on opposite sides of nanostructures of the P-type transistor in the X-direction;
silicide features over and in contact with the first source/drain features and the second source/drain features, wherein a shortest distance from the silicide features to the substrate in a Z-direction is less than a distance from bottom surfaces of topmost nanostructures of the nanostructures of the N-type transistor and the P-type transistor to the substrate in the Z-direction; and
source/drain contacts over and in contact with the silicide features.

18. The semiconductor device of claim 17, wherein a longest distance from the silicide features to the substrate in the Z-direction is greater than the distance from the bottom surfaces of the topmost nanostructures of the nanostructures of the N-type transistor and the P-type transistor to the substrate in the Z-direction.

19. The semiconductor device of claim 17, further comprising:
a gate via over and in contact with the gate structure, wherein top surfaces of the source/drain contacts are substantially level with a bottom surface of the gate via.

20. The semiconductor device of claim 17, wherein each of the source/drain contacts has a V-shaped bottom surface in an X-Z cross-sectional view,
wherein lowest points of the V-shaped bottom surfaces are about 1 nm to about 10 nm lower than top surfaces of the topmost nanostructures of the nanostructures of the N-type transistor and the P-type transistor.
